(19) United States
(12) Patent Application Publication
(10) Pub. No.: US 2016/0035924 A1
(43) Pub. Date: Feb. 4, 2016

(54) CONFIGURABLE BACKPLANE INTERCONNECTING LED TILES

(71) Applicant: Nthdegree Technologies Worldwide Inc., Tempe, AZ (US)

(72) Inventors: Bradley Steven Oraw, Chandler, AZ (US); Bemly Sujeewa Randeniya, Chandler, AZ (US); Travis Thompson, Chandler, AZ (US)

(21) Appl. No.: 14/884,693

(22) Filed: Oct. 15, 2015

Related U.S. Application Data
(63) Continuation-in-part of application No. 14/559,609, filed on Dec. 3, 2014.
Application No. 14/559,609 is a continuation-in-part of application No. 14/731,129, filed on Jun. 4, 2015.
Application No. 14/731,129 is a continuation-in-part of application No. 14/162,257, filed on Jan. 23, 2014, now Pat. No. 9,074,758.
(60) Provisional application No. 62/215,570, filed on Sep. 8, 2015.
(60) Provisional application No. 61/947,573, filed on Mar. 4, 2014.
(60) Provisional application No. 61/763,295, filed on Feb. 11, 2013.
(60) Provisional application No. 61/763,295, filed on Feb. 11, 2013.

(51) Int. Cl. H01L 31/05; H01L 33/62; H01L 27/15

(52) U.S. Cl. CPC H01L 31/0508; H01L 27/156; H01L 33/62

(57) ABSTRACT

Relatively small, electrically isolated LED tiles or PV tiles are fabricated having an anode electrode and a cathode electrode. The LED tiles contain microscopic printed LEDs that are connected in parallel by two conductive layers sandwiching the LEDs. The top conductive layer is transparent. Separately formed from the tiles is a large area backplane having a single layer or multiple layers of metal traces connected to backplane electrodes corresponding to the tile electrodes. Multiple tiles are laminated over the backplane's metal pattern to connect the tile electrodes to the backplane electrodes, such as by a conductive adhesive. The backplane metal pattern may connect the tiles in series and/or parallel, or form an addressable circuit for a display. Groups of tiles may be physically connected to each other prior to the lamination to ease handling and alignment. The backplane has power terminals electrically coupled to the metal traces for receiving power.

### CROSS-REFERENCE TO RELATED APPLICATIONS

This application claims the benefit of U.S. provisional application Ser. No. 62/215,570, filed Sep. 8, 2015, and is a continuation-in-part (CIP) of U.S. application Ser. No. 14/559,609, filed Dec. 3, 2014, by Bradley S. Oraw and Bemly S. Randeniya, and is a CIP of U.S. application Ser. No. 14/731,129, filed Jun. 4, 2015, by Travis Thompson and Bradley S. Oraw, all applications being assigned to the present assignee and incorporated herein by reference.

### FIELD OF THE INVENTION

This invention relates to light sheets formed using distributed light emitting diodes (LEDs) and, in particular, to a technique of interconnecting segmented areas of the LEDs.

### BACKGROUND

The present assignee has developed a printable LED light sheet where microscopic inorganic LED chips, having a top electrode and a bottom electrode, are printed as an ink on a conductive layer on a thin substrate. Such LEDs are called vertical LEDs. After the ink is cured, the bottom electrodes of the LEDs make electrical contact to the conductive layer. A dielectric layer is then deposited between the LEDs, and another conductive layer is printed to make electrical contact to the top electrodes of the LEDs to connect the LEDs in parallel. A suitable voltage is applied to the two conductive layers to illuminate the LEDs. To allow light to escape, one or both of the conductive layers is transparent. Indium tin oxide (ITO) or sintered silver nano-wires are preferred for the transparent conductive layer. With nano-wires, after the nano-wire ink is printed and cured, the nano-wires form a sintered mesh with spaces between the nano-wires to allow the light to pass.

One desired application of the light sheet technology is for large area lamps, such a 2×4 foot lamp to replace conventional fluorescent troffers. Other large area applications are envisioned, such as addressable displays.

The practical sheet resistance of the printed ITO layer is typically 50-100 Ohms/square and, for silver nano-wires, it is typically about 5-10 Ohm/square. For large light sheets, the currents conducted by the conductive layers are large so there will be significant voltage drops across the light sheet resulting in brightness non-uniformity. Thicker layers of the transparent conductor can lower the resistance, but this limits transparency, makes it more difficult to fabricate, reduces flexibility, and adds cost. As a result, the transparent conductive layer can only be optimized for a relatively small LED light sheet, limiting the practicality of using the technology for large area light sheets.

What is needed is a technique for forming a larger area LED light sheet of any size that does not suffer from the above-described problems with the transparent conductive layer. Further, the technique should allow the lamp to be formed using a roll-to-roll process.

### SUMMARY

Relatively small segments of identical LED light sheets are fabricated having an anode terminal and a cathode terminal. A single segment can range from a few square centimeters to up to 25 cm² or more. Each segment will typically contain at least 5 LEDs and possibly hundreds of LEDs, depending on the desired size and brightness of each segment. The anode terminal may be along one edge of the light sheet segment, and the cathode terminal may be along the opposite edge. The terminals may be on the side of the light sheet segment that is opposite to the light emission side. The microscopic LEDs printed in each segment are connected in parallel by two conductive layers sandwiching the vertical LEDs. At least one of the conductive layers is transparent and formed of an ITO layer, a silver nano-wire mesh, or another type of transparent conductor. Such transparent conductive layers have a sheet resistance that is much higher than a solid metal layer, such as an aluminum or copper layer, but are made thin to optimize transparency and flexibility. One of the conductive layers terminates with the anode terminal and the other of the conductive layers terminates with the cathode terminal. The terminals may be more robust metal layers that have been printed on the light sheet segment.

Since the segments are small, there is not much current carried by the conductive layers so the conductive layers may be thin without a significant voltage drop across the segment. Therefore, there is good brightness uniformity across each segment.

The segments are very flexible and may be less than 100 microns thick.

Separately formed from the light sheet segments is a flexible, larger area conductor backplane having a single layer or multiple layers of solid metal strips (traces) that interconnect the segments and connect them to power supply terminals. The metal strips have very low resistance and can carry large currents without any significant voltage drop. The metal strips have raised bumps that contact the anode and cathode terminals of the light sheet segments when the segments are mounted over the backplane, such as during a roll-to-roll lamination process.

An adhesively layer covers the top surface of the backplane, and the raised bumps extend above the adhesive layer.

The light sheet segments are aligned with the backplane and pressed in position over the backplane to adhesively secure the segments to the backplane and make the various electrical interconnections between the metal bumps and the segment terminals. The adhesive may be flexible after curing. The arrangement of the metal strips on the backplane and the raised bumps determine how the segments will be electrically connected. Some connection possibilities include: segments in parallel, segments in series, addressable segments for brightness control, and addressable columns and rows of segments for a display. For a practical display, the segments may be about a square centimeter or any larger size. A practical minimum size for a square segment is about 4 mm². For column and row metal strips, the backplane contains multiple layers of metal strips that are insulated from one another by a thin dielectric layer. The pitch of the metal strips can be less than 1 mm. In one embodiment, the backplane supports a single linear array of segments connected in series and/or parallel to form a narrow light strip of any length. In another embodiment, the backplane supports a two-dimensional array of segments to replace a 2×4 foot fluorescent troffer.

In another embodiment, the segments are not physically separated from each other but are printed on a single large substrate (e.g., a plastic film) and electrically isolated from one another. Using this technique, the handling of the segments and alignment of the segments (being a single unit) relative to the backplane are simplified.

The invention also applies to mounting identical photovoltaic tiles (solar tiles) to a configurable backplane, where the backplane connects the anode and cathode electrodes on the back surface of the tiles in any configuration, such as to connect the tiles in any combination of series and parallel.

Other embodiments are described.

### BRIEF DESCRIPTION OF THE DRAWINGS

FIG. 1 is a cross-section of an LED light sheet segment and a conductor backplane being brought together. The backplane portion shown is part of a much larger backplane and the segment shown may be on the same dielectric substrate as an array of electrically isolated segments.

FIG. 2 illustrates the light sheet segment and backplane after being pressed together.

FIG. 3 is a simplified perspective view of a light sheet segment being aligned with electrodes (raised bumps) on the backplane.

FIG. 4 is a top down view of a section of a possibly much larger lamp, showing four segments mounted over strips of metal conductors on the backplane, where addressable channels are formed using multiple columns of metal strips.

FIG. 5 illustrates an addressable system of segments using row and column strips on the backplane, where row strips contact cathode terminals and column strips contact anode terminals.

FIG. 6 illustrates an addressable system with column strips for higher resolution addressing compared to FIG. 4.

FIG. 7 illustrates an addressable system with row and column strips with higher resolution compared to FIG. 5.

FIG. 8 illustrates how any number of segments may be connected in series. A series string may be addressable or connected in parallel with other series strings.

FIG. 9 illustrates how a shaped pixel (a star, circle, square, etc.) can be individually addressed using row and column strips on the backplane.

FIG. 10 illustrates how a linear array of segments may be connected in parallel or series to form a narrow light sheet of any length. Any other shape can be fabricated.

FIG. 11 is a schematic cross-section of a simple light sheet segment mounted on a single-layer backplane, where one backplane electrode contacts the anode terminal of the segment along one edge, and the other backplane electrode contacts the cathode terminal of the segment along the other edge. The bumps on the backplane are shown distorting the top surface of the thin light sheet segment. The segment may be on the same dielectric substrate with an array of segments, or the segment may be physically separate.

FIG. 12 illustrates the use of multiple conductor layers on the backplane, such as for row and column strips.

FIG. 13 illustrates how the anode and cathode terminals on the light sheet segment may be on the top light exit surface, where connections between the backplane conductors and the segment terminals are made by conductors that wrap around the edges of the segment. Conductive vias through the segment can also be used.

FIG. 14 illustrates an alternative design for a front-to-front electrical connection between the segment terminals and the backplane electrodes.

FIG. 15 illustrates how the LED/conductive layers can be printed directly on the metal strips of the backplane so no separate substrate of the segment is needed.

FIG. 16 illustrates the use of multiple backplanes being stacked so the metal strips on the backplanes are connected in parallel to conduct any amount of current with insignificant voltage drops.

FIG. 17 is a perspective view illustrating how the backplane sheet can be aligned with the segments using mechanical alignment or optical alignment.

FIG. 18 illustrates how a roll-to-roll process can be used for the adhesive deposition, the lamination of the segments to the backplane, and the curing of the adhesive.

FIG. 19 illustrates how the backplane is separately formed to have an adhesive layer and a protective liner film over the adhesive so the backplane can be stored on a roll. Later, the backplane roll is provided in a roll-to-roll process where the liner is removed and the segments are laminated onto the backplane, as shown in FIG. 18.

FIG. 20 is a front view of a single LED tile with an edge connector.

FIG. 21 is a back view of the LED tile of FIG. 20.

FIG. 22 illustrates multiple tiles being connected together.

FIG. 23 is a side view of the connected tiles.

FIG. 24 illustrates two LED tiles being connected together.

FIG. 25 illustrates LED tiles mounted on a backplane for interconnecting the tiles.

FIG. 26 illustrates addressing different portions of a single LED tile.

FIG. 27 illustrates an addressable display containing LED tiles.

FIG. 28 illustrates mechanically coupled, but electrically isolated, LED tiles being interconnected by traces on a backplane.

FIG. 29 illustrates how LED tiles can be connected in parallel and in series via backplane.

FIG. 30 shows the various layers of the structure of FIG. 29.

FIG. 31 illustrates how strips of conductors on the back of LED tiles may initially connect LED tiles in parallel.

FIG. 32 illustrates how the parallel conductors of FIG. 31 may be cut using a laser.

FIG. 33 illustrates a dielectric layer encapsulating the ends of the cut conductors.

FIG. 34 illustrates filling in grooves or cuts with an opaque material for reducing cross-talk between pixels.

FIG. 35 illustrates the electrodes on the backs of connected LED tiles forming an LED sheet.

FIG. 36 illustrates cutting the LED sheet with a laser to have any shape or size.

FIG. 37 illustrates a dielectric layer for encapsulating the edges of the cut LED sheet.

FIG. 38 illustrates filling in grooves or cuts with an opaque material for reducing cross-talk between segments.

FIG. 39 illustrates a color filter positioned over the top surface of LED tiles emitting white light to create a color display.

FIG. 40 illustrates red and green phosphor layers over blue-emitting LED tiles to create a color display.

FIG. 41 illustrates filling in grooves or cuts with an opaque material for reducing cross-talk between pixels.

FIG. 42 illustrates layers used in an embodiment of an LED lamp.

FIG. 43 illustrates addressing LED tiles using row and column conductors.

FIG. 44 illustrates layers used in an LED display with row and column conductors, where an anisotropic conductor layer is used to connect the LED tiles to the backplane.

FIG. 45 illustrates how a conductive bump ink layer may be used to add height to a conductor for a more reliable connection to the anisotropic conductor layer.

FIG. 46 illustrates how a non-conductive adhesive layer with conductive vias may be used to connect the LED tiles to the backplane.

FIG. 47 illustrates the use of traces on both sides of the backplane, where some of the traces are connected together using conductive through-vias in the backplane.

FIG. 48 illustrates how the LED tiles may be formed as adhesive labels and later affixed to a customized backplane for interconnecting the tiles.

FIG. 49 illustrates how modules of LED tiles may be connected in parallel using edge terminals.

FIG. 50 illustrates how LED tiles may be connected by breakable tabs to a continuous rail to ease fabrication.

FIG. 51 illustrates an expandable strip of LED tiles, where FIG. 51 shows a side view of the unexpanded structure, a front view of the unexpanded structure, and a front view of the expanded structure.

FIG. 52 illustrates how LED tiles may be electrically and mechanically connected at pivot points so that the string of LED tiles may have a customized shape.

FIG. 53 illustrates how the backplane has a flexible area between LED tiles for bending.

FIG. 54 illustrates a spring connection in the backplane between the LED tiles for bending the strip of LED tiles in the X, Y, and Z directions. A front view and a side view are shown.

FIG. 55 is a front view of a two-dimensional array of LED tiles where the spring connection in the backplane allows the array of LED tiles to have any 3-D shape.

FIG. 56 illustrates the layers in the structure of FIG. 55.

FIG. 57 illustrates a curved backplane mounting surface and a conformable back surface of an LED tile for connection to the backplane.

FIG. 58 illustrates flexible features of a backplane between LED tiles in an array of LED tiles for bending the array.

FIG. 59 illustrates how groups (modules) of any number of LED tiles can be connected to respective module backplanes for interconnecting the LED tiles in each module, and how the backplanes may be connected to a larger system backplane for interconnecting the modules, enabling the formation of very large displays, such as billboards.

FIG. 60 illustrates the layers used in the structure of FIG. 59.

FIG. 61 illustrates layers used in a lamp structure having front components and back components on a backplane, where the backplane has through-vias.

FIG. 62A illustrates a front surface of a thin, flexible photovoltaic (PV) tile with anode and cathode electrodes on its back surface for connection to a configurable backplane.

FIG. 62B illustrates the back of the tile of FIG. 62A.

FIG. 63 illustrates how identical PV tiles may be connected in any combination of series and parallel, and possibly to other circuits, by mounting the tiles on a backplane having a configurable pattern of metal traces.

Elements that are similar or identical in the various figures are labeled with the same numeral.

### DETAILED DESCRIPTION

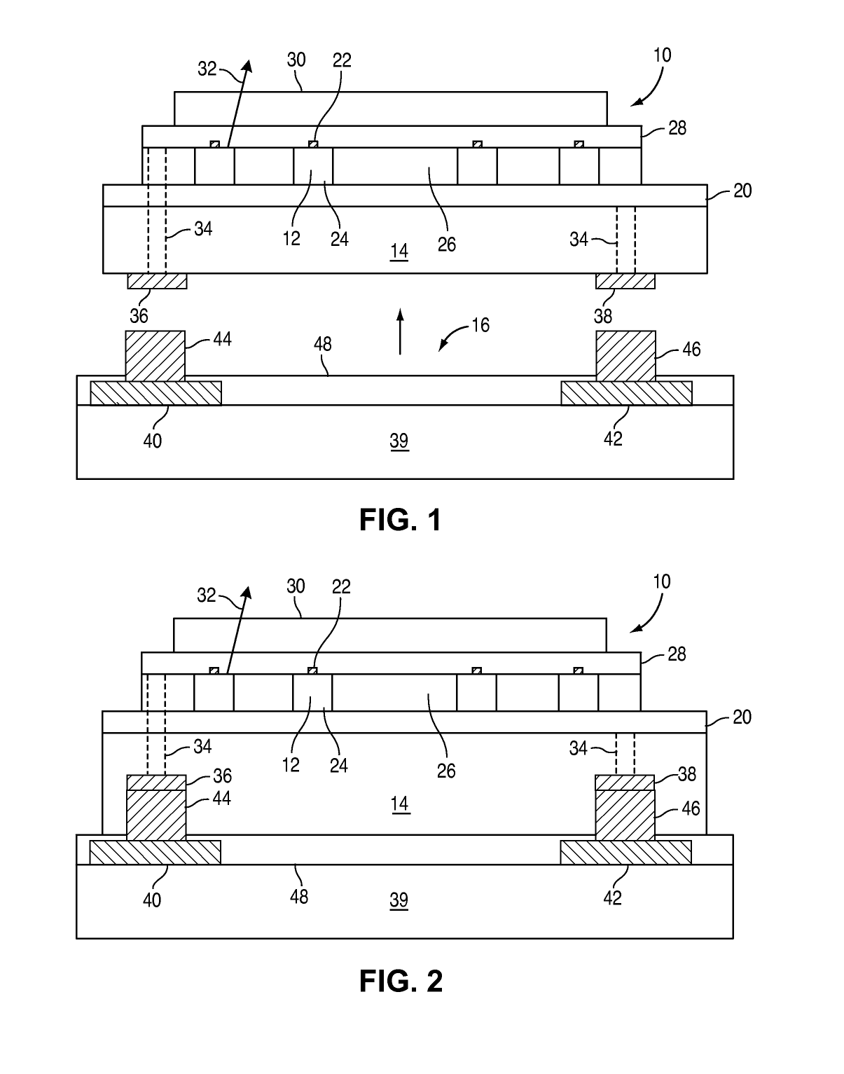

FIG. 1 is a cross-section of a single light sheet segment 10 containing at least the four LEDs 12 shown. The segment 10 can be any size. Typically, to form the segments 10, a much larger light sheet is formed and then die cut to form the individual identical segments 10. Since a minimum practical die cut segment is about 2 mm per side, the minimum size segment 10 may be 4 mm². Such a small size may be used for an addressable display. Even though the LEDs are printed as an ink and are randomly located, the density of the LEDs in the ink can be made so that it is virtually assured that a plurality of LEDs will be located within each segment 10, such as an average of at least five LEDs. The LEDs may be printed in pre-defined areas down to about 1 mm² using screen printing, flexography, or other types of printing methods. For normal lighting applications, a single segment 10 will be much larger, such as up to 1 or 2 feet per side, depending on the current requirements, and contain hundreds of microscopic LEDs.

In another embodiment, multiple segments are formed on a single dielectric substrate 14 and the segments are not singulated. In such a case, the segments are pre-aligned with respect to each other on the substrate 14 by the printing process but electrically isolated from each other on the substrate 14. Their interconnections and/or connections to a power supply will be determined by a metal pattern on a separate backplane 16 that is laminated to the segments. Laminating a plurality of segments on a single substrate 14 to the backplane 16 eases handling and alignment compared to separately laminating singulated segments 10 to the common backplane 16. In such a case, the segment's LED/conductive layers would be identically repeated as an array on the substrate 14 of FIG. 1, with a gap between each segment for electrically isolating them, and the segments would remain on the same substrate 14 when laminated to the backplane 16. The invention applies equally to electrically isolated segments supported on the same substrate 14 and to singulated segments. The same backplane 16 supports any number of segments 10.

The LED light sheet segment 10 may be formed as follows.

A starting substrate 14 may be polycarbonate, PET (polyester), PMMA, Mylar, other type of polymer sheet, or other material. In one embodiment, the substrate 14 is about 12-250 microns thick and may include a release film.

A conductor layer 20 is then deposited over the substrate 14, such as by printing. The substrate 14 or conductor layer 20 may be reflective. For enhancing flexibility, the conductor layer 20 may be a sintered silver nano-wire mesh.

A monolayer of microscopic inorganic LEDs 12 is then printed over the conductor layer 20. The LEDs 12 are vertical LEDs and include standard semiconductor GaN layers, including an n-layer, and active layer, and a p-layer. GaN LEDs typically emit blue light. The LEDs 12, however, may be any type of LED, based on other semiconductors and/or emitting red, green, yellow, or other color light, including light outside the visible spectrum, such as the ultraviolet or infrared regions.

The GaN-based micro-LEDs 12 are less than a third the diameter of a human hair and less than a tenth as high, rendering them essentially invisible to the naked eye when the LEDs 12 are spread across the substrate 14 to be illuminated. This attribute permits construction of a nearly or partially transparent light-generating layer made with micro-LEDs. In one embodiment, the LEDs 12 have a diameter less than 50 microns and a height less than 20 microns. The number of micro-LED devices per unit area may be freely adjusted when applying the micro-LEDs to the substrate 14. The LEDs 12 may be printed as an ink using screen printing or other forms of printing. Further detail of forming a light source by printing microscopic vertical LEDs, and controlling their orientation on a substrate, can be found in US application publication US 2012/0164796, entitled, Method of Manufacturing a Printable Composition of Liquid or Gel Suspension of Diodes, assigned to the present assignee and incorporated herein by reference.

In one embodiment, an LED wafer, containing many thousands of vertical LEDs, is fabricated so that the top metal electrode 22 for each LED 12 is small to allow light to exit the top surface of the LEDs 12. The bottom metal electrode 24 is reflective (a mirror) and should have a reflectivity of over 90% for visible light. In the example, the anode electrode is on top and the cathode electrode is on the bottom.

The LEDs 12 are completely formed on the wafer, including the anode and cathode metallizations, by using one or more carrier wafers during the processing and removing the growth substrate to gain access to both LED surfaces for metallization. The LED wafer is bonded to the carrier wafer using a dissolvable bonding adhesive. After the LEDs 12 are formed on the wafer, trenches are photolithographically defined and etched in the front surface of the wafer around each LED, to a depth equal to the bottom electrode, so that each LED 12 has a diameter of less than 50 microns and a thickness of about 4-20 microns, making them essentially invisible to the naked eye. A preferred shape of each LED is hexagonal. The trench etch exposes the underlying wafer bonding adhesive. The bonding adhesive is then dissolved in a solution to release the LEDs from the carrier wafer. Singulation may instead be performed by thinning the back surface of the wafer until the LEDs are singulated. The LEDs 12 of FIG. 1 result. The microscopic LEDs 12 are then uniformly infused in a solvent, including a viscosity-modifying polymer resin, to form an LED ink for printing, such as screen printing or flexographic printing.

The LED ink is then printed over the conductor layer 20. The orientation of the LEDs 12 can be controlled by providing a relatively tall top electrode 22 (e.g., the anode electrode), so that the top electrode 22 orients upward by taking the fluid path of least resistance through the solvent after printing. By providing a heavier bottom electrode 24, the LEDs 12 also self-orient. The anode and cathode surfaces may be opposite to those shown. The locations of the LEDs 12 are random, but the approximate number of LEDs 12 printed per unit area can be controlled by the density of LEDs 12 in the ink. The LED ink is heated (cured) to evaporate the solvent. After curing, the LEDs 12 remain attached to the underlying conductor layer 20 with a small amount of residual resin that was dissolved in the LED ink as a viscosity modifier. The adhesive properties of the resin and the decrease in volume of resin underneath the LEDs 12 during curing press the bottom cathode electrode 24 against the underlying conductor layer 20, creating a good electrical connection. Over 90% like orientation has been achieved, although satisfactory performance may be achieved with only 50% of the LEDs being in the desired orientation for a DC driven lamp design. 50% up and 50% down is optimal for lamps that are powered with AC.

A transparent polymer dielectric layer 26 is then selectively printed over the conductor layer 20 to encapsulate the sides of the LEDs 12 and further secure them in position. The ink used to form the dielectric layer 26 pulls back from the upper surface of the LEDs 12, or de-wets from the top of the LEDs 12, during curing to expose the top electrodes 22. If any dielectric remains over the LEDs 12, a blanket etch step may be performed to expose the top electrodes 22.

To produce a lamp that emits upward and away from the substrate 14, conductor layer 28 may be a transparent conductor, such as ITO or sintered silver nano-wires forming a mesh, which is printed to contact the top electrodes 22. The conductor layer 28 is cured by lamps to create good electrical contact to the electrodes 22.

The LEDs 12 in the monolayer, within each segment 10, are connected in parallel by the conductor layers 20/28 since the LEDs 12 have the same orientation. Since the LEDs 12 are connected in parallel, the driving voltage will be approximately equal to the voltage drop of a single LED 12.

A flexible, transparent, polymer protective layer 30 may be printed over the transparent conductor layer 28. The layer 30 may instead represent a phosphor layer for wavelength-conversion of the LED light. In one embodiment, the LEDs 12 emit blue light and the phosphor is a YAG phosphor emitting yellow-green light so that the composite light is white.

When the LEDs 12 are energized by a voltage potential across the conductor layers 20/28, very small and bright blue dots are visible. A blue light ray 32 is shown.

If the terminals of the segment 10 are to be on the bottom of the substrate 14, conductive vias 34 may be formed by coating a hole with a conductive material. The vias 34 terminate in metal terminals 36 and 38, electrically coupled to the conductor layers 28 and 20, respectively.

The backplane 16 uses a substrate 39 that may be the same dielectric material as the substrate 14, or any other flexible material, and may also be 12-250 microns thick. The backplane 16 substrate 39 may instead be a rigid material of any thickness. The backplane 16 can be any size, which will typically be the size of the resulting lamp, including a 2×4 foot lamp to replace conventional fluorescent troffers. Any number of segments 10 may be mounted on the same backplane 16.

A metal pattern is formed on the backplane substrate 39 for connecting the segment terminals 36/38 to a power source. The metal pattern may interconnect the segments 10 in any manner or connect each segment separately to a row/column addressing circuit to form an addressable display.

Cross-sections of metal strips 40 and 42 are shown in the example of FIG. 1. The metal may be aluminum, copper, silver, solder, or any other metal or alloy. The metal may be plated, sputtered, printed, laminated foil, etched, lifted off, or formed in any other manner. The thickness and widths of the metal strips 40 and 42 are that required to handle the operating current without significant voltage drop across the lamp.

Metal bumps 44 and 46 are formed on the metal strips 40 and 42 at locations corresponding to the segment 10 terminals to be contacted.

A dielectric adhesive layer 48 is deposited over the surface of the backplane 16 and is of a thickness to allow the bumps 44 and 46 to extend above the adhesive layer. In one example, the bumps 44 and 46 are about 50 microns high and the adhesive layer 48 is about 25 microns thick, so the bumps 44/46 extend about 25 microns above the adhesive layer 48. The adhesive layer may be blanket deposited or deposited using a mask. The adhesive pulls off the bumps by surface tension. The adhesive may be UV or thermally cured or be a pressure sensitive adhesive with a suitable bonding strength.

FIG. 2 illustrates the resulting structure after the segment 10 and backplane 16 have been pressed together to laminate the two layers, such as in a roll-to-roll process. The cured adhesive is flexible so that the resulting lamp may be bent without delamination.

In one embodiment, the substrate 14 is resilient so the metal bumps 44 and 46 extend into the substrate 14 somewhat to make a very good electrical contact with the segment terminals 36 and 38, where the adhesive layer 48 essentially encapsulates the electrical connections.

The metal bumps 44 and 46 may be any metal, such as a printed or otherwise deposited silver, nickel, zinc, carbon, copper, aluminum, etc. If printed as an ink, the metal ink is cured, such as with UV or heat. In another embodiment, the metal bumps 44 and 46 are formed of a solder, and the structure is heated to flow the solder. The bumps 44 and 46 may also be a conductive epoxy.

FIG. 3 illustrates the segment 10 terminals 36/38 being aligned with the bumps 44/46 prior to lamination. As previously mentioned, the segments need not be singulated but may all be supported on the same substrate 14 and electrically isolated prior to being mounted on the backplane 16.

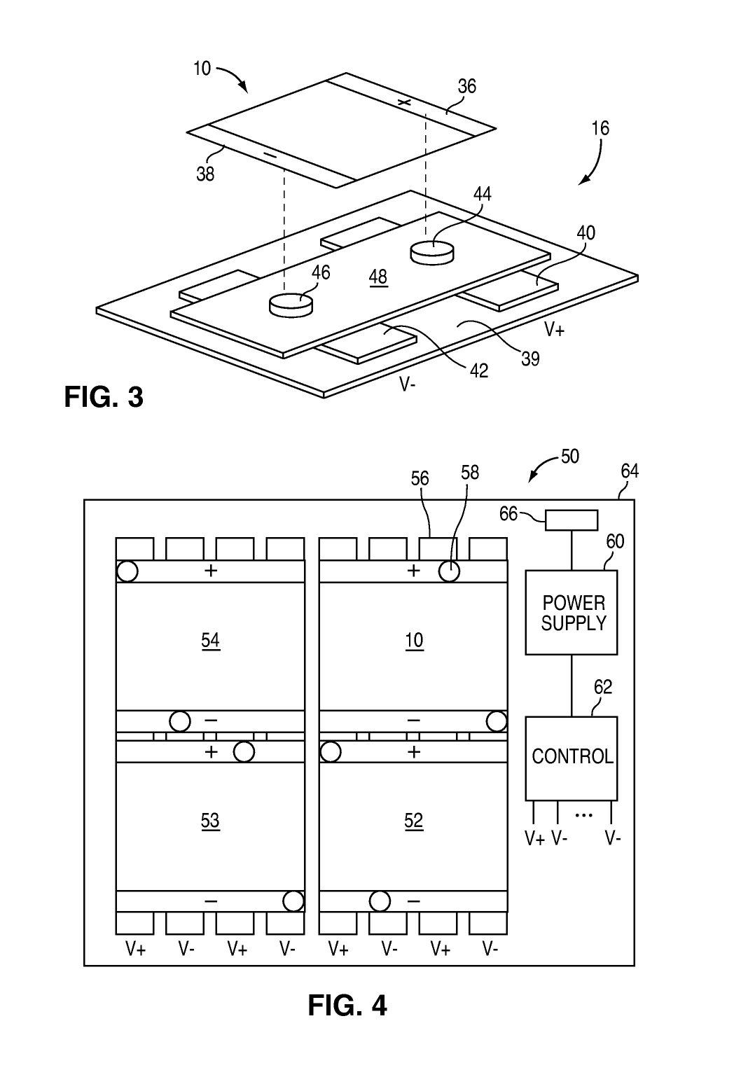

FIG. 4 illustrates one type of metal pattern on a backplane 50. In the example, four segments 10, 52, 53, and 54 are shown laminated to the backplane. The anode and cathode terminals of the segments are labeled + and −, respectively. The metal pattern forms metal column strips 56, and the metal bumps 58 are located to contact the desired terminals of the segments. In the example, there are eight strips 56, where each segment is electrically connected to two of the strips 56. This allows each of the four segments to be individually driven by a power supply 60 and a controller 62. There may be many more segments connected to the various strips 56 so that multiple segments are connected in parallel, and all segments in parallel may be addressed by energizing a pair of column strips 56. The selective control of the segments may control the brightness of the lamp, create a display, change the overall output color of the lamp if the segments contain different colors of LEDs or phosphors, or achieve other functions.

The power supply 60 and controller 62 may be formed on the backplane substrate 64 and have a connector 66 for receiving 120 VAC and digital control signals for selectively energizing the strips 56.

By interconnecting the segments and/or driving the segments via the robust metal pattern on the backplane 50, large currents may be carried with little voltage drop. The thin conductive layers in the segments can have fairly high sheet resistances without a significant voltage drop since the conductive layers need only conduct the current for the LEDs in that segment. Therefore, the ITO layer or silver nano-wire mesh can be thin and transparent, improving efficiency. Additionally, identical segments can be produced, and the electrical interconnections can be customized on the various backplanes for different applications.

The entire lamp thickness may be less than 0.5 mm and the lamp can be very flexible.

In another embodiment, the metal pattern on the backplane may connect all segments in parallel using, for example, a serpentine pattern of two metal strips under each segment where one strip is connected to the anode terminal and the other strip is connected to the cathode terminal of each segment. Any number of segments may be mounted on the backplane.

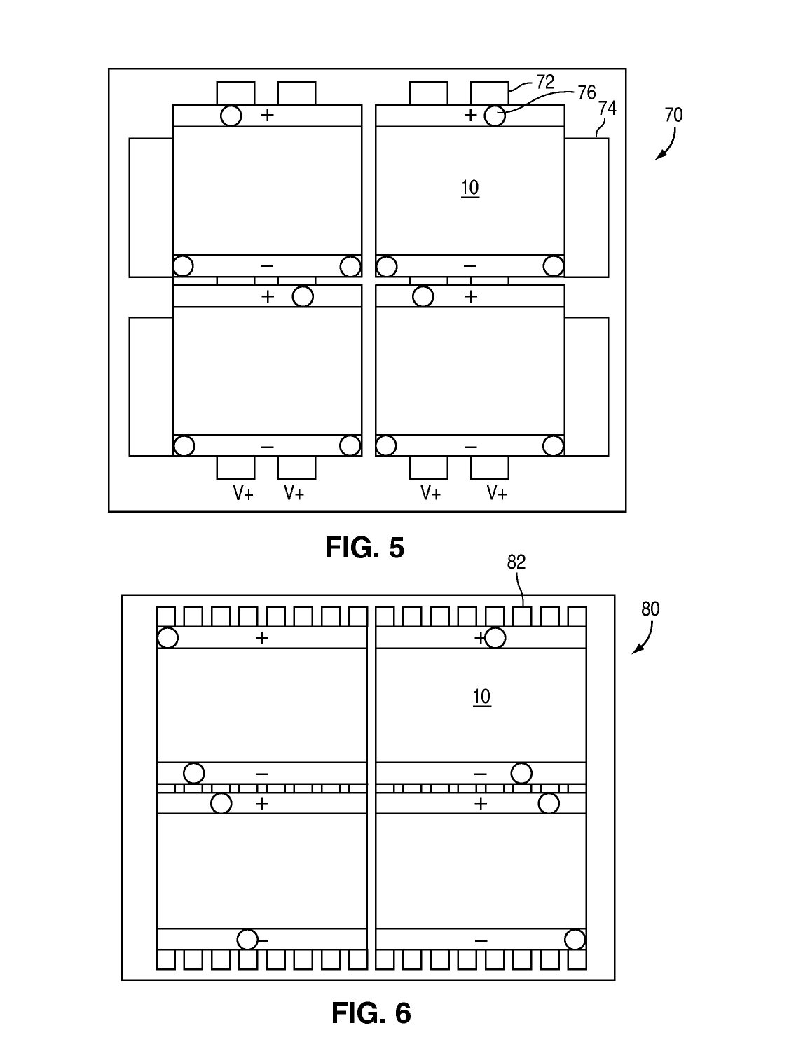

FIG. 5 illustrates another backplane 70 metal pattern where metal column strips 72 and metal row strips 74 contact the terminals of four segments via the metal bumps 76. Any of the four segments can be energized by applying a driving voltage across a combination of a row strip and a column strip. A much larger array of segments and strips can be used to create an addressable display of any size. The segments may be as small as 4 mm² or be 100 cm² or larger.

FIG. 6 illustrates a portion of a backplane 80 with 16 metal column strips 82 for selectively energizing two columns of segments with four segments per column. The metal bumps are illustrated by the small circles in the various figures.

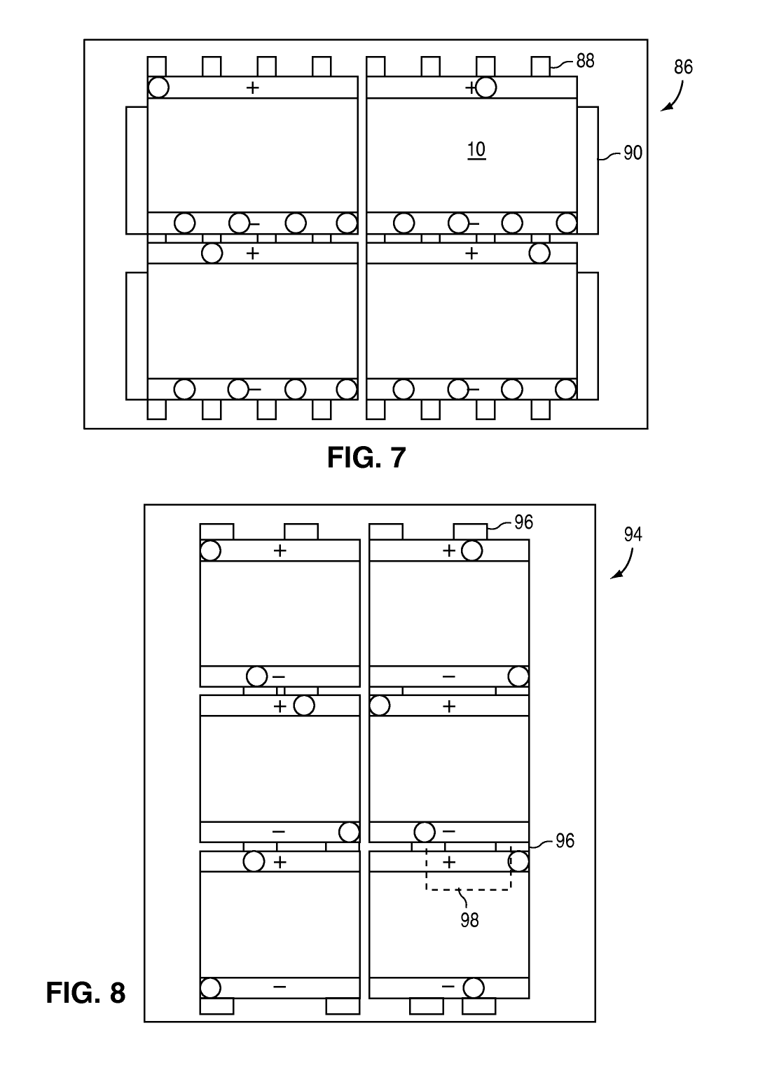

FIG. 7 illustrates a portion of a backplane 86 with column strips 88 and row strips 90, where four segments per column can be individually addressed by energizing combinations of column and row strips.

FIG. 8 illustrates a backplane 94 having isolated metal areas 96 that connect segments in series. The dashed line 98 represents how a pair of metal areas 96 are connected together on the backplane 94 below the segments. The columns of segments (connected in series) may be connected in parallel, or the columns may be connected in series.

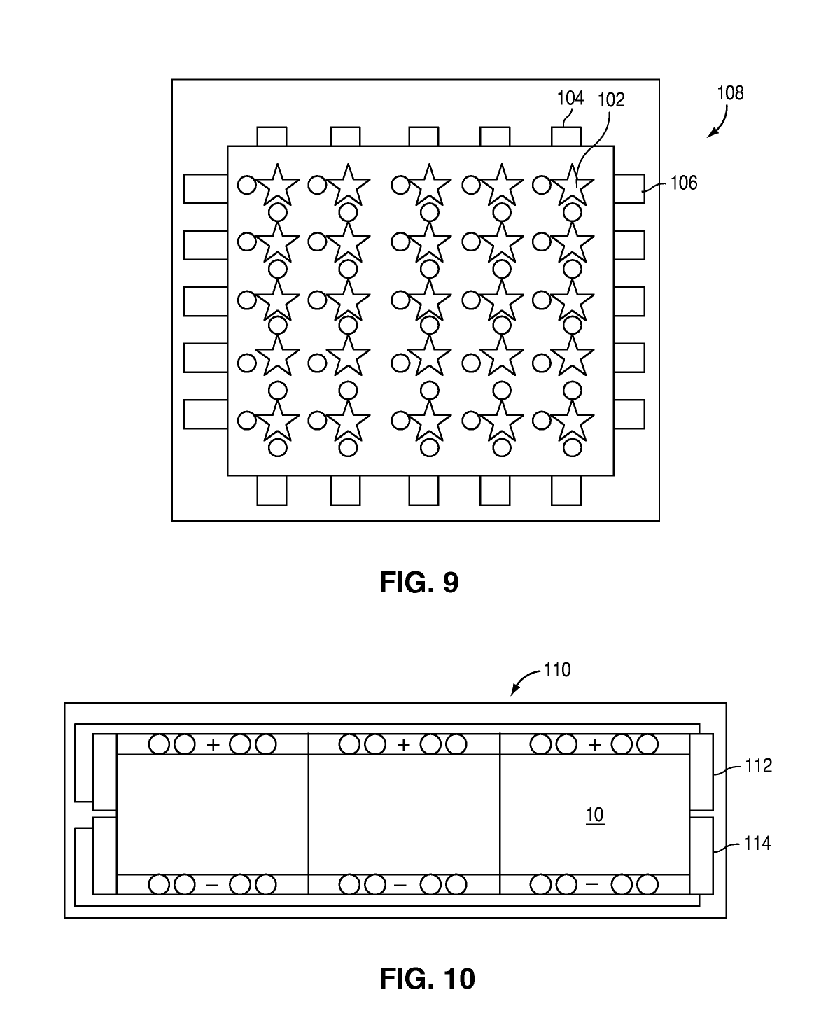

FIG. 9 illustrates how each segment 102 may form a star or any other shape, such as an alpha-numeric character, a square, a circle, etc. Each segment 102 is connected to a unique combination of a column strip 104 and a row strip 106 on the backplane 108 so each segment can be individually addressable using a controller, such as shown in FIG. 4. Each segment 102 may form a pixel in a display or form a separate character, such as a letter or number. Multiple segment colors may be used to form a full color display.

FIG. 10 illustrates how the backplane 110 contains two row strips 112 and 114 to form a narrow and long backplane 110 for connecting any number of segments 10 in parallel in a linear array. The backplane 110 can be cut to any length. A connector, such as a plug or socket, may be affixed to the end of the backplane 110 for connection to a power source.

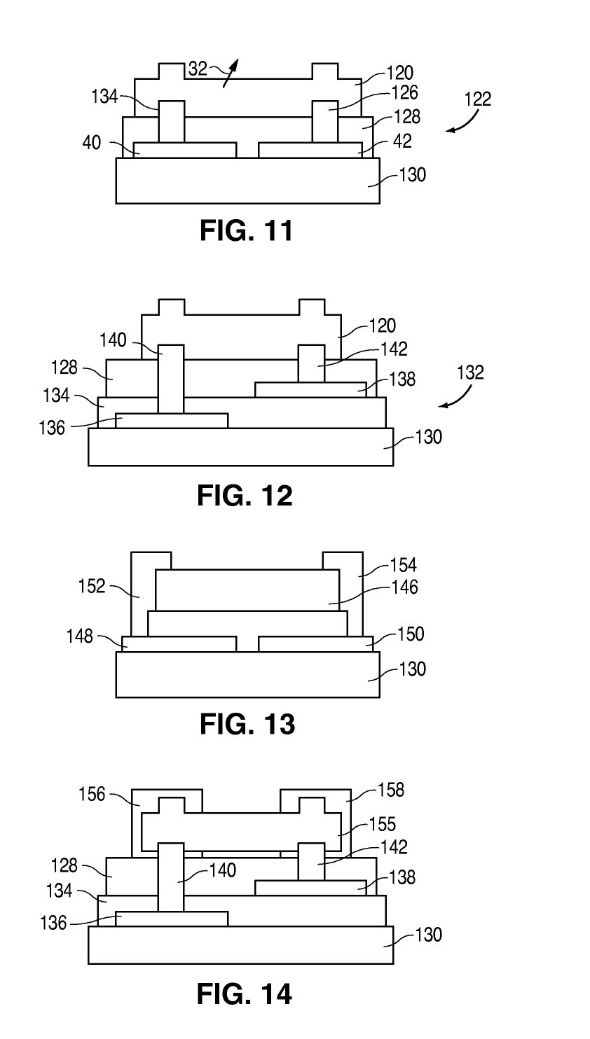

FIG. 11 is a schematic cross-section of a simple light sheet segment 120 mounted on a single-metal-layer backplane 122, where one backplane electrode bump 134 contacts the anode terminal of the segment 120 along one edge, and the other backplane electrode bump 126 contacts the cathode terminal of the segment 120 along the other edge. The bumps 124/126 on the backplane 122 are shown distorting the top surface of thin light sheet segment 120. The metal strips 40/42 may be parallel column strips. The adhesive layer 128 and backplane substrate 130 are also shown.

FIG. 12 illustrates the use of multiple conductor layers on the backplane 132, such as for overlapping row and column strips. A dielectric layer 134 insulates the metal strip 136 from the overlying metal strip 138 where they overlap. The bumps 140/142 contact the segment 120 terminals.

FIG. 13 illustrates how the anode and cathode terminals on the light sheet segment 146 may be on the top light exit surface, where connections between the backplane metal strips 148/150 (or areas) and the segment 146 terminals are made by conductors 152/154 (straps) that wrap around the edges of the segment 146. Conductive vias through the segment 146 can also be used. Other types of conductors are envisioned.

FIG. 14 illustrates an alternative design for a front-to-front electrical connection between the segment 155 top terminals and the backplane electrode bumps 140/142. In this embodiment, conductors 156/158 wrap around the edges of the segment 155 to make the connection.

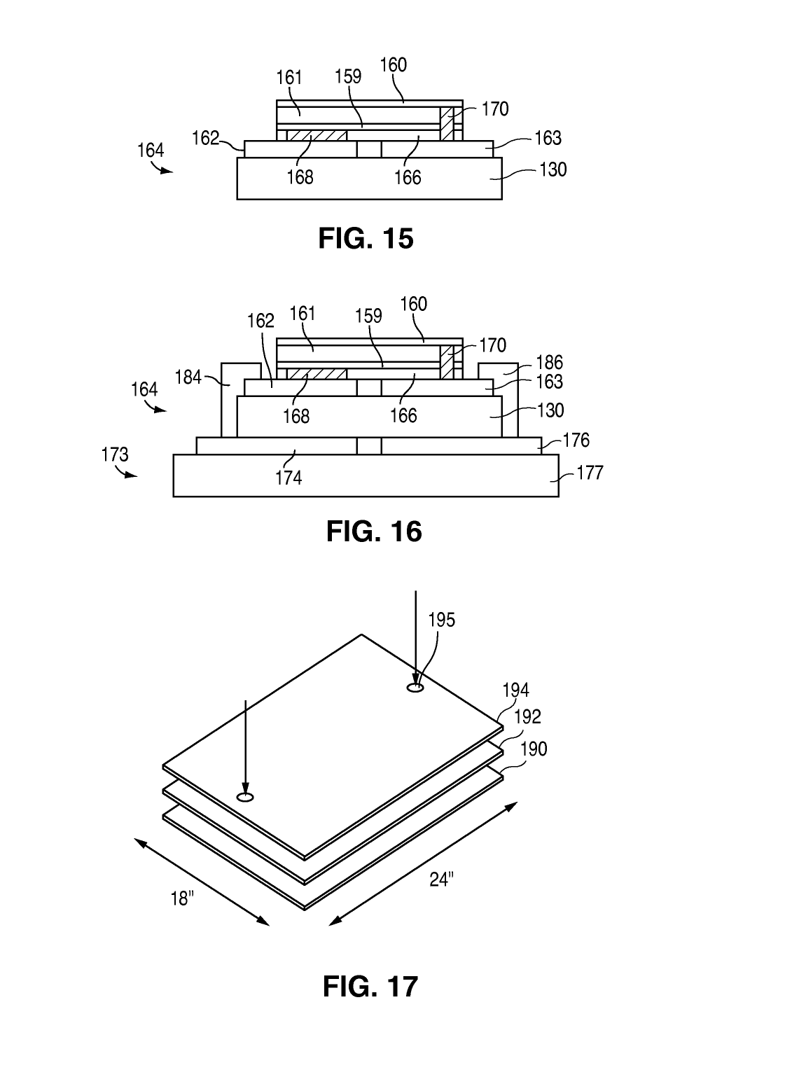

FIG. 15 illustrates how the conductive layers 159/160 and LED layer 161 (forming a segment) can be printed over the metal strips 162/163 of the backplane 164 so no separate substrate of the LED/conductive layers is needed. The top conductive layer 160 is transparent. A dielectric layer 166 is formed over and between the metal strips 162/163, followed by printing the LED/conductor layers. Conductive vias 168/170 are formed to connect the metal strips 162/163 to the conductive layers 159/160. All of the segments can be printed simultaneously over the same backplane 164.

FIG. 16 illustrates the use of multiple backplanes 164/173 being stacked so the metal strips on the backplanes are connected in parallel to conduct any amount of current with insignificant voltage drops. Metal strips 174 and 176 are formed on the backplane substrate 177, and metal strips 162 and 163 are formed on the backplane substrate 130. The metal strips 174 and 162 are connected together via the side conductor 184, and the metal strips 176 and 163 are connected together via the side conductor 186. Additional backplanes can be stacked to conduct higher currents, depending on the size of the lamp. The ends of the four metal strips are connected to a power source. The LED/conductive layers may be printed over the top backplane 164 as in FIG. 15, or the segment 10 of FIG. 1 may be mounted to the top backplane 164.

As in all embodiments, the backplane may be the approximate size of the entire lamp and connects all the segments to a power source. The backplane may interconnect multiple light sheet segments together or create an individually addressable display. Also, in all embodiments, an array of segments may be supported by the single substrate 14 of FIG. 1 or the segments can be singulated prior to being mounted on the backplane.

FIG. 17 is a perspective view illustrating how the backplane substrate 190, having an adhesive layer 192, can be aligned with an LED light sheet 194, having one or more segments, using mechanical alignment or optical alignment. In the example shown, holes 195 are precisely located in the light sheet 194 that align with holes through, or marks on, the backplane, followed by a lamination step. Mechanical or optical means may be used for the alignment. Since the light sheet 194 may be transparent, alignment marks can be printed on the light sheet 194 instead of holes, and the alignment marks are aligned with alignment marks on the backplane. In the example shown, the lamp is 18×24 inches, and the light sheet 194 may contain any number of segments, such as over 1000, that are interconnected and/or coupled to a power source via the metal strips (or metal areas) on the backplane substrate 190.

Since the LED light sheet and backplane may be a fraction of a millimeter thick, they are highly flexible and light. As such, the lamination process may be performed in a roll-to-process. Since the LED light sheet and the backplane metal pattern can be formed by printing, they can also be formed in a roll-to-roll process.

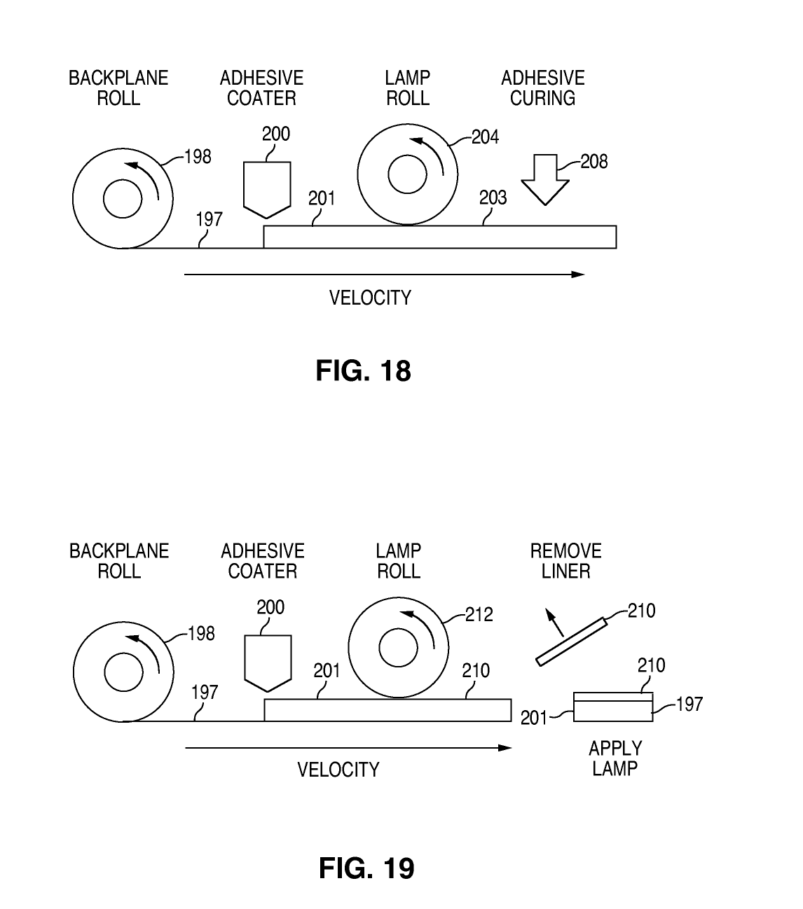

FIG. 18 illustrates how a roll-to-roll process can be used for the adhesive deposition, the lamination of the segments to the backplane, and the curing of the adhesive. The backplane substrate 197 with the metal pattern is provided on a roll 198. An adhesive coater 200 applies a thin coat of an adhesive 201 over the metal pattern, while allowing the metal bumps (e.g., bumps 44/46 in FIG. 1) to extend above the adhesive layer. Electrically isolated light sheet segments 203 on a common substrate (e.g., substrate 14 of FIG. 1) are provided on a lamp roll 204, and the segments 203 are laminated to the backplane under pressure to make the electrical connections between the segments 203 and the metal pattern (shown in FIGS. 1-3). The adhesive 201 is then cured at a curing station 208, such as by heat or UV (since the segments may be semi-transparent). The resulting laminated lamp may be then taken up by a take-up roller or cut to form the individual lamps and stacked as sheets. Power supplies and controllers (if needed) may be mounted on the backplane and connected to the metal strips.

FIG. 19 illustrates how the backplane is separately formed to have an adhesive layer and a protective liner film over the adhesive so the backplane can be stored on a roll. The backplane substrate 197 the metal pattern is provided on a roll 198, and an adhesive coater 200 applies a thin coat of an adhesive 201 over the metal pattern, as described above. A thin liner sheet 210 is provided on a liner roll 212 and protects the uncured adhesive 201 as the resulting backplane is taken up by a take-up roller (not shown) for later use. When the backplane is to be laminated to the segments, as shown in FIG. 18, the liner sheet 210 is peeled off during the roll-to-roll process, and the segments are laminated onto the backplane, as shown in FIG. 18.

The manufacturing cost of the resulting lamp is reduced since the backplane metal can be any conventional metal formed using any process rather than a metal optimized for use in the light sheet segment whose formation must be compatible with the segment fabrication process. Further, since the segments may be identical, only the backplane needs to be customized for a particular application.

Since the resulting lamp is very thin and flexible, a semi-rigid frame may be used to support the lamp, such as for a ceiling fixture or for a vertical display. Alternately, the thin lamp may be directly affixed to any flat or curved surface. Baseboard, wall, under-shelf, and other types of lighting applications are also envisioned.

All features described herein may be combined in various combinations to achieve a desired function.

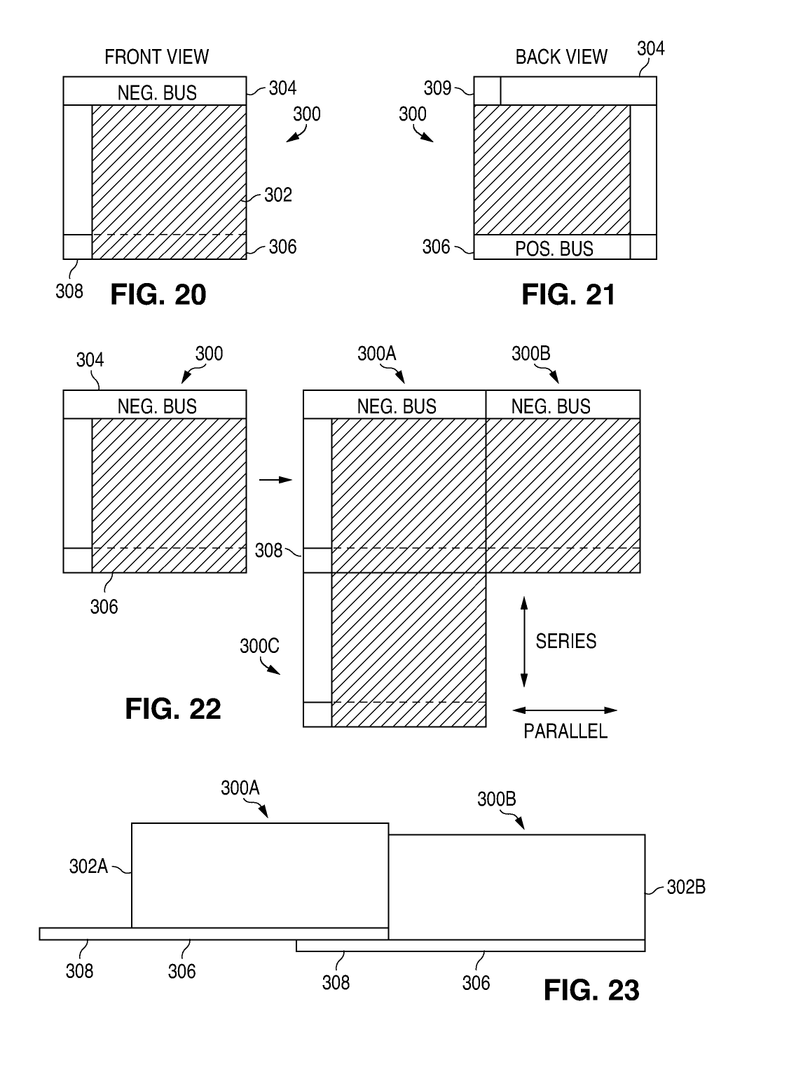

FIG. 20 is a front view of another embodiment of a light emitting tile 300 that can be connected seamlessly in series or in parallel with other identical tiles without any perceptible gaps in the light output. FIG. 21 is a back view of the tile of FIG. 20. The thin, flexible light sheet of FIG. 1 may be supported by a rigid or semi-rigid support to form the tile 300 or the tile 300 itself may be the thin, flexible light sheet.

The seamless connection between tiles is achievable by the light emitting portion 302 of the tile 300 extending all the way to two contiguous edges, where the other two contiguous edges on the top side form non-light generating areas used for interconnections between tiles, and where the underside of the tile 300 also supports interconnections between tiles. Abutting tiles overlap the non-light generating areas on the top side of one of the tiles. When tiles are interconnected together, only the light emitting areas are visible.

The light emitting portion 302 contains one or more layers of printed LEDs, as described with respect to FIG. 1. The cathode leads of the LEDs terminate in a negative bus 304, running along the top edge of the tile 300, and the anode leads of the LEDs terminate in an exposed positive bus 306, running along the bottom edge of the tile 300.

The metal interconnection areas of the negative bus 304 and the positive bus 306 are exposed on the left edge of the front side of the tile 300 of FIG. 20. An edge portion 308 of the positive bus 306, for interconnection, is shown exposed on the front side of the tile. The remainder of the positive bus 306 is behind the light emitting portion 302. The metal interconnection areas of the negative bus 304 and the positive bus 306 are also exposed on the right edge of the underside side of the tile 300 in FIG. 20. FIG. 21 shows an edge portion 309 of the negative bus 304, for interconnection, exposed on the back side of the tile 300.

The busses 304 and 306 may be a metal foil laminated to the tiles, or may be the flexible substrate 14 of FIG. 1 coated with a metal layer, or may be other forms of conductors. Some possible types of interconnections for electrically connecting the buses of interconnected tiles are discussed later.

FIG. 22 illustrates identical tiles 300, 300A, 300B, and 300C being physically and electrically coupled together. When the tiles are interconnected vertically, they are connected in series because the positive bus 306 on the underside of one tile overlaps and connects to the negative bus 304 of the top side of other tile, as shown with tiles 300A and 300C.

When the tiles are interconnected horizontally, they are connected in parallel because the positive bus 306 on the underside of one tile overlaps and connects to the exposed positive bus edge portion 308 on the top side of the other tile, as shown with tiles 300A and 300B, and the exposed edge portion 309 of the negative bus 304 on the underside of one tile overlaps and connects to the negative bus 304 on the top side of the other tile.

The terms vertically and horizontally, or rows and columns, refer to the relative angles of the directions and are not required to have any absolute direction in space. For example, in an actual embodiment of a large display using the interconnected tiles, mounted vertically, a row may be either vertical or horizontal.

By being able to connect some of the tiles in series and some in parallel, the required overall supply current for an interconnected set of tiles is less than if all the tiles were connected in parallel.

In another embodiment, the positive and negative buses may be arranged so that all the tiles are connected in parallel. In another embodiment, the positive and negative buses may be arranged so that the parallel and series connection is made external to the tile set.

Since the configuration of the tiles allows the light emitting portions 302 of adjacent tiles directly abut, there is no light gap, enabling the interconnected tiles to be a large seamless display or a general light source. The term “seamless” in this context means that there is no perceptible extra gap (dark area) between abutting light generating areas of the interconnected tiles.

FIG. 23 is a side view of two abutting tiles 300A and 300B connected together, where the light emitting portions 302A and 302B abut, and the metal bottom edge of the positive bus 306 of the tile 300A overlies and electrically contacts the metal top edge portion 308 of the positive bus 306 of the tile 300B. The negative buses 304 are similarly interconnected, with the metal bottom edge portion 309 (FIG. 21) of the negative bus 304 of tile 300A overlapping and electrically connecting to the top metal edge of the negative bus 304 of the tile 300B.

FIGS. 20-23 illustrate metal bus connectors that may make electrical contact by just overlapping their metal portions, or by using a conductive adhesive between the overlapping bus portion, or by using clips on the backs of the tiles to push the metal bus portions together, or by using male and female connectors, or by using springs, or by using solder, or by using any other type of connector mechanism. The interconnections may be permanently made by the manufacture, or the user may make the interconnections.

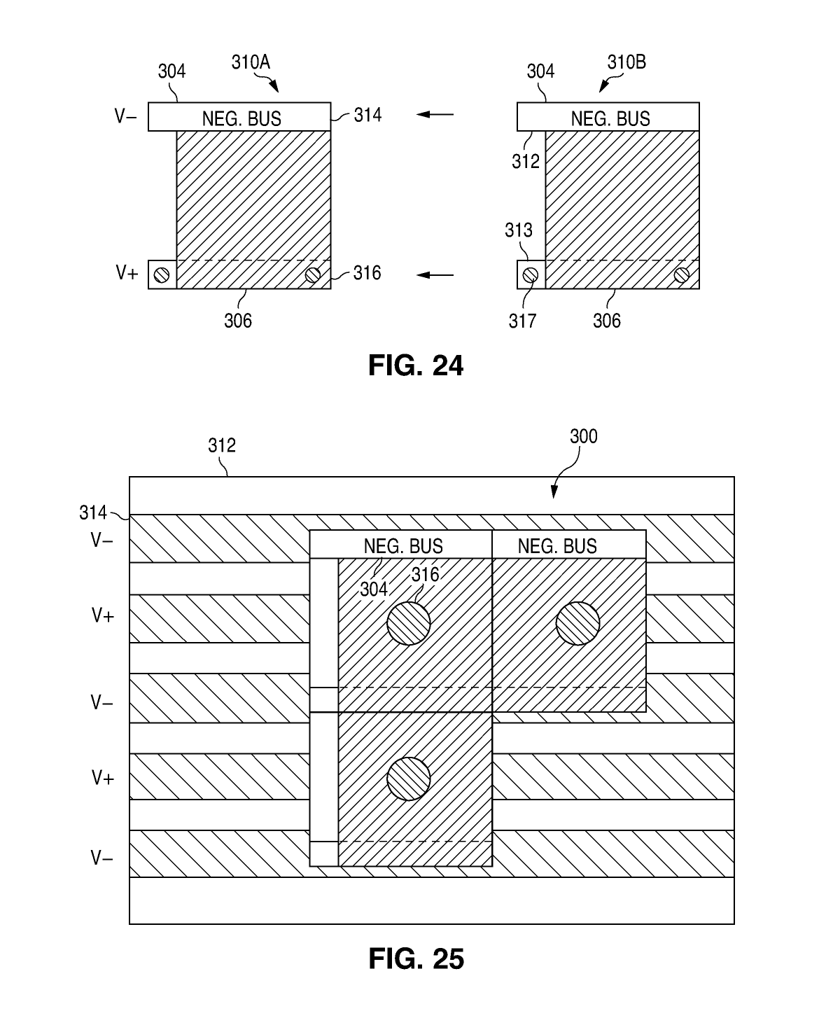

FIG. 24 illustrates how the identical tiles 310A and 310B may include male and female connectors that electrically and physically connect the tiles in the horizontal direction. The tiles may be connected in the vertical direction with similar connectors or with other types of connectors. In FIG. 24, the male tabs 312 and 313 are inserted into slots 314 and 316 when interconnecting the tiles 310A and 310B. For the vertical interconnection, the positive bus 306 may have a male tab, and the negative bus 304 may have a slot for connecting tiles in series in the vertical direction. If all the tiles are to be connected in parallel, the connections for the negative and positive buses may be provided at each of the four edges of the tiles.

FIG. 24 also illustrates how the tiles may include alignment marks 317 to help the user align the tiles.

If the tiles are relatively large, narrow opaque metal strips may be formed over the transparent conductor to better spread current.

Since the tiles may be very thin and flexible, a customizable rigid or semi-rigid backplane may be used for supporting the interconnected tiles and for providing the electrical interconnections.

FIG. 25 illustrates how tiles 300 may be mounted on a common backplane 312 for physical support and for electrically connecting the tiles 300 in any combination of series and parallel, via the backplane conductors 314. The backplane conductors 314 alternate between connected to a cathode voltage (V−) and an anode voltage (V+). The negative buses 304 directly overlap the backplane's cathode conductors, and the positive buses (on the back of the tiles) overlap the backplane's anode conductors at the connection point represented by a dot 316. In such tiles, the positive bus runs along the middle of the tiles. The tiles 300 may be affixed to the backplane 312 with an adhesive.

Since all the bus conductors 314 run horizontally, the tiles in each row are connected in parallel, and the bus conductors 314 may be externally interconnected to connect any number of rows in series and/or parallel. The backplane 312 may be simply cut to the desired size. Connectors or wires at one or both ends of the backplane 312 may be used to interconnect the backplane conductors 314 in any manner and apply power to the interconnected tiles.

The traces and circuitry on the backplane 312 may be customized for any application, such as for use as a light panel for general illumination or for individually addressing each of the tiles (or portions of the LEDs in each tile) for a display.

Since there is no gap between the interconnected tiles, the tiles may be used for creating an addressable display of any size.

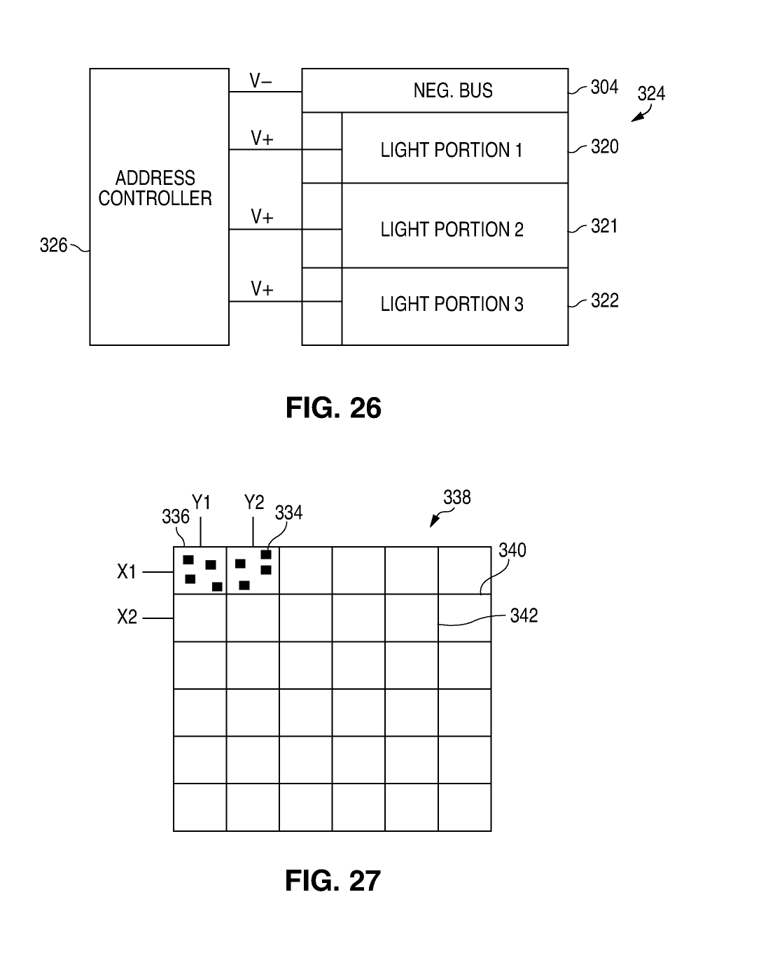

FIG. 26 illustrates how groups of printed LEDs 320, 321, and 322 in a tile 324 can be separately addressed by an address controller 326. The cathode voltage (V−) is applied to the negative bus 304 for all the groups of LEDs. To turn on any group of LEDs, a positive anode voltage (V+) is applied to the selected group of LEDs. For interconnected tiles, the various conductors are provided on a backplane, and access to the conductors may be provided on the edge of the backplane via a connector.

Although printing LEDs results in a generally random distribution of printed LED dies, the LEDs can be printed in small groups, where all the LEDs in a group are connected in parallel and are addressable as a group. Each group of microscopic LED dies may include 3-5 LEDs, and the groups are printed as addressable pixels in an ordered matrix. Pixels may be red, green, and blue by using phosphors or by printing different types of LEDs. Such ordered groups of LEDs may be printed using screen printing, flexography, or other types of printing. By controlling the currents to the RGB pixels, via narrow conductive traces, a wide gamut of colors is achievable. Even if the pixels contain slightly different numbers of LEDs, the brightness of the pixels will be the same if the same current is supplied to each pixel.

Each of the conductors on the back or front of a tile can supply an anode voltage to a selected pixel in a tile to turn it on. To reduce the number of conductors, a tile may be addressed by applying a cathode voltage to it (such as by a row conductor), then the pixel within that tile is addressed by applying the anode voltage to a single conductor (a column conductor). Alternatively, all tiles have a continuous cathode voltage applied to them, and each anode conductor for each pixel is brought out to the edge of a backplane. A controller then supplies the appropriate anode voltage level to each conductor for illuminating the selected pixels with the proper current for the displayed image. Other addressing schemes are envisioned. In the example shown, each tile is 8×8 inches, but tiles may be as small as 5×5 mm².

The anode conductors and cathode conductors may be the opposite, where there is a separate cathode conductor for each pixel and there is a common anode conductor for a tile.

FIG. 27 illustrates groups of LEDs 334 printed as a 6×6 matrix of pixels 336 in a single tile 338. The LEDs in each group are connected in parallel. By simultaneously supplying a row (X1, X2, . . . ) and column (Y1, Y2, . . . ) drive voltage to the conductors 340 and 342, the addressed LEDs in a pixel will be illuminated.

The tiles shown herein are rectangular (includes a square), but other shapes are possible, such as hexagons or triangles.

Printed LED lights possess many degrees of design freedom. As such, development time for custom light design can be costly. Risk of design failure must be mitigated by validation with costly development print runs. Hence, standard light designs are preferred to minimize engineering costs. However, most customers prefer custom light designs to meet specific performance, form factor, or assembly requirements. Therefore, providing generic LED sheets with customizable backplanes for the electrical interconnections are preferred over an integrated solution.

Additional concepts are described below using generic tiles of LED sheets, where each tile may be a single pixel (or single color sub-pixel) or a small portion of a lighting panel. Each tile has an anode and cathode conductor that is electrically connected to an interconnection pattern on a separate backplane. All interconnections may be made via the backplane, so only the backplane needs to be customized for a particular size display or lighting panel. In the example of a color display, each LED tile may be a square about 3-5 mm per side, forming a single addressable pixel, and the tiles are arranged on a backplane. The tiles may be physically connected together, but electrically isolated, during the fabrication process to simplify handling when attaching to the backplane. An array of LED tiles may form abutting red, green, and blue pixels. Red and green phosphors may overlie the LED tiles containing blue-emitting GaN-based LED dies.

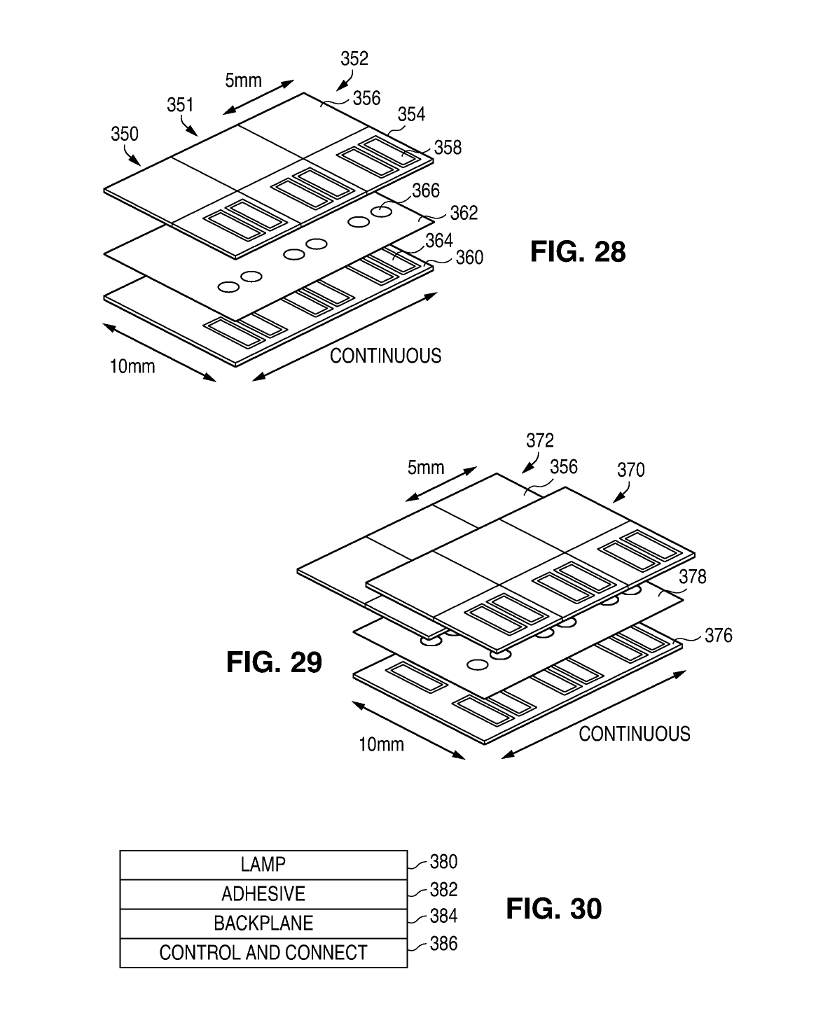

FIG. 28 illustrates three, initially electrically isolated LED tiles 350, 351, 352 formed as part of a continuous strip in a roll-to-roll process. The tiles 350-352 are formed on the same substrate, such as the substrate 14 in FIG. 1. Each tile is identical and comprises an anode/cathode electrode area 354 and an LED area 356. The anode and cathode metal 358 may extend through the entire tile so that it may be electrically contacted from the top side or the bottom side. The LED area 356 comprises printed, microscopic LED dies sandwiched between two conductor layers for connecting the LED dies in parallel, where at least one of the conductor layers is transparent, as previously described. Any density of LED dies can be achieved.

In one embodiment, each tile is 5 mm wide and 10 mm long. If the tiles were used in a full color display, each sub-pixel (for a single color) is therefore 5×5 mm², and the three tiles form a single RGB pixel. The pixel area can be formed down to about 2×2 mm² using current printing technology.

The strip of tiles can be cut to any length, but it is assumed below that the three tiles have been cut from the continuous strip of tiles.

The LED area 356 may be covered with a phosphor or quantum dot layer to create red, green, and blue addressable pixels using only printed GaN-based blue-emitting LED dies.

The tiles 350, 351, and 352 may be generic for any size display or illumination panel. The customization of the display or panel is by means of a configurable backplane 360 and an adhesive interconnection layer 362. Anode and cathode metal electrodes 364 are shown on the front surface of the backplane 360, which align with the tile electrodes. These electrodes 364 are interconnected in any manner by traces (not shown) on the front or back surface of the backplane. The configuration of the traces may be by printing an interconnect metal pattern, followed by copper plating. The metal pattern may also be defined by a resist pattern, and the exposed metal is etched away, similar to the process used to form certain printed circuit boards. In the example, it is assumed the backplane 360 connects the three tiles 350-352 in series.

The adhesive interconnection layer 362 is a laser-cut stencil. In one embodiment, the layer 362 is a 3M™ Thermal Bonding Film 583, which is about 0.05 mm thick and slightly tacky. A conductive epoxy 366 fills the through-holes in the layer 362 after the layer 362 is bonded to the backplane 360. The epoxy-filled holes align with the backplane 360 and tile electrodes 358.

The tiles 350-352 are then positioned over the layer 362 and affixed using heat and pressure to electrically and mechanically connect the tiles 350-352 to the backplane 360.

The backplane 360 has a termination area (not shown) at its edge that connects to a power source. The termination may be a multi-pin male or female connector.

If the tiles 350-352 were part of a color display, the tiles 350-352 may emit red, green, and blue light, respectively, and would be individually addressable by the trace pattern on the backplane 360. Many groups of the RGB pixels would be arranged in an array on the backplane 360 to form a display of any size. The backplane 360 may be formed of a very thin (e.g., less than 10 mils) and flexible sheet of plastic (e.g., PET), and the resulting display or panel may be rolled up for storage. Separate segments of the display or panel may be mechanically and electrically interconnected at their edges to build a display or panel of any size.

In one embodiment, the backplane 360 is a continuous strip 10 mm wide and supports any number of tiles connected in series and/or parallel to provide the desired voltage and current characteristics. Each tile may emit white light. The strips may be used for under-cabinet lighting, accent lighting, car lighting, or any other application. The strips may be cut to any length.

Due to the human eyes' sensitivity to various colors, an additional green sub-pixel tile may be added, resulting in a 2×2 array of tiles (forming a single, full-color pixel), where the green tiles would be diagonally positioned in the 2×2 array. The number of sub-pixels of a particular color may be further modified to achieve the proper balance between the red, green, and blue emissions.

In another embodiment, two-dimensional LED sheets and backplanes can be printed rather than strips.

The adhesive interconnect layer 362 may be a commercially available anisotropic conductor (ACF) film (conducts only in the Z direction), rather than a stenciled film. The layer 362 may also be a printed, thermal-setting anisotropic conductive adhesive (ACA). Solder may also be used for the interconnection.

FIG. 29 illustrates connecting identical tiles 372 and 370 in parallel via the backplane 376 interconnection pattern. FIG. 29 illustrates two sets of physically connected tiles, with three tiles in each set, where the two overlapping tiles may be connected in parallel, and the three sets of parallel tiles being connected in series with each other. The backplane 376 performs all of the interconnections connections. An automatic positioning machine may be used to rapidly populate the backplane 376 and interconnection layer 378 with the tiles.

FIG. 30 illustrates the various layers of the customizable structure with a generic lamp layer 380, a conductive adhesive layer 382, and a backplane layer 384. The backplane layer 384 has the customized control circuitry and interconnection circuitry 386 formed on its front or back surface for electrically interconnecting the LED tiles. The control circuitry may include addressing circuitry for RGB pixels or may simply control the current to the entire array of LED areas.

The LED areas 356 abut each other so there are no gaps between the LED areas in the X and Y directions (i.e., seamless).

The various tiles may be initially formed in a roll-to-roll process as a continuous strip or two-dimensional array of electrically isolated tiles. The LED sheet may then be cut to any size, such as by using a laser. The LED sheet may then be applied to the backplane 360 to simplify handling.

Since the various layers may be formed of moldable plastic films, the structure (including the LED sheet and backplane) may be molded, such as by heat and pressure, to create any shape. Molding may be used to achieve a desired light emission profile. The flexible structure may be used for form curved backlights for LCD screens. Additionally, the structure may be placed in a mold and encapsulated using a transparent or diffusive material to form a rigid structure of any shape. The structure can be molded into any object, such as a frame, etc. The mold itself may even become part of the object if a portion of the mold was transparent. In another embodiment, the LED portion and the backplane may be molded separately and then connected together.

Since all layers may be formed of transparent materials, such as transparent plastic films, the LED emission may exit through the backplane layer or through the opposite side. Any conductors may be transparent conductors, such as ITO. If voltage drop across the ITO is problematic, thin opaque metal traces may run across the tiles to better spread current.

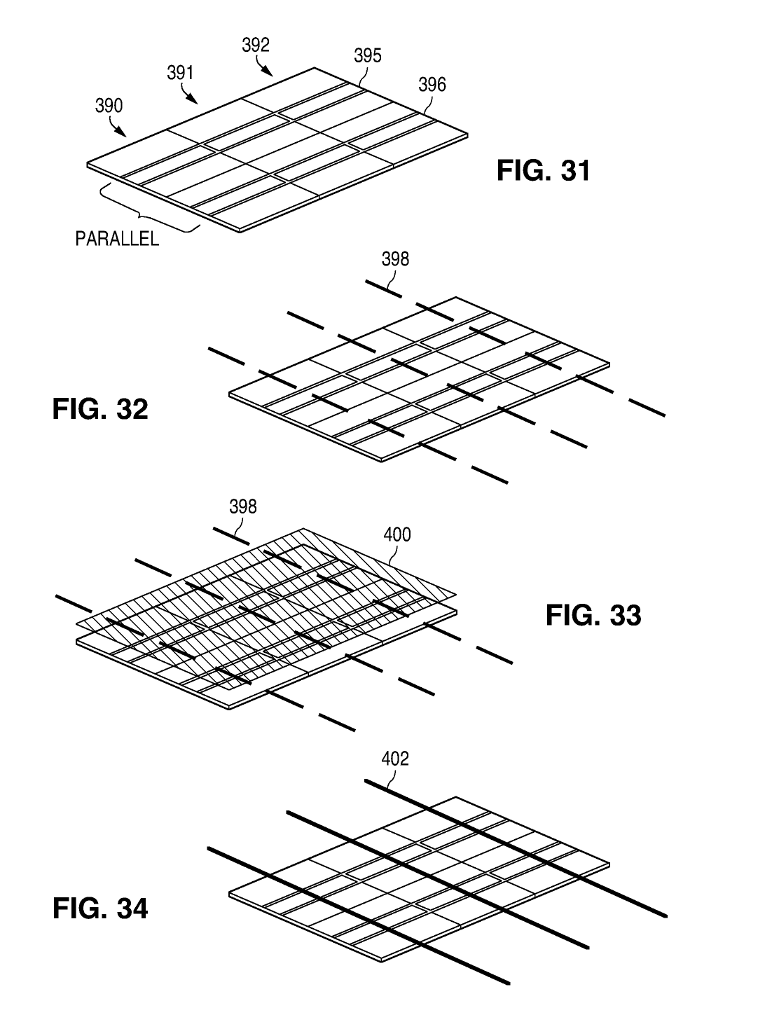

FIGS. 31-34 illustrate other techniques for electrically contacting the LED dies in the LED areas of the tiles.

FIG. 31 shows the back surface of three tiles 390, 391, and 392, with either half of each tile being an LED area or the entire top surface of each tile being an LED area. The tiles may be initially formed as a continuous strip. Anode and cathode conductors 395 and 396, respectively, may be continuous along the strip. Therefore, the LED areas are initially connected in parallel. Thus, the backplane does not need to provide the parallel interconnections if such parallel connections were desired to be maintained. Any number of tiles may be connected in the strip.

If the tiles are to be individually addressable, such as for a display, the tiles or just the conductors may be cut with a laser, as shown in FIG. 32, across lines 398 to electrically isolate the conductors and LED areas. For a display, multiple strips of tiles may be used to form a two-dimensional array of tiles.

In FIG. 33, the back surface of the tiles is covered with a dielectric layer 400 to encapsulate the cut edges and mechanically affixed the tiles together. Openings (not shown) in the dielectric layer 400 are formed to expose the conductors for each tile for connection to the backplane electrodes for individually addressing the tiles.

In FIG. 34, an opaque material 402 may be deposited in the cut grooves between the tiles for reducing cross-talk between pixels and to maximize contrast. The light emission surface is on the side opposite to the surfaces shown in FIGS. 31-34. Since the LED area may take up the entire front surface of each tile, no overlap of tiles is needed when creating a two-dimensional array of tiles.

In one embodiment, all the tiles use blue-emitting LED dies, and a phosphor (e.g., YAG) is deposited over the LED areas to emit white light. Color filters may be laminated over the array of tiles for the red, green, and blue pixels. Alternatively, the tiles may use red and green phosphors to directly emit the red, green, and blue light for the pixels.

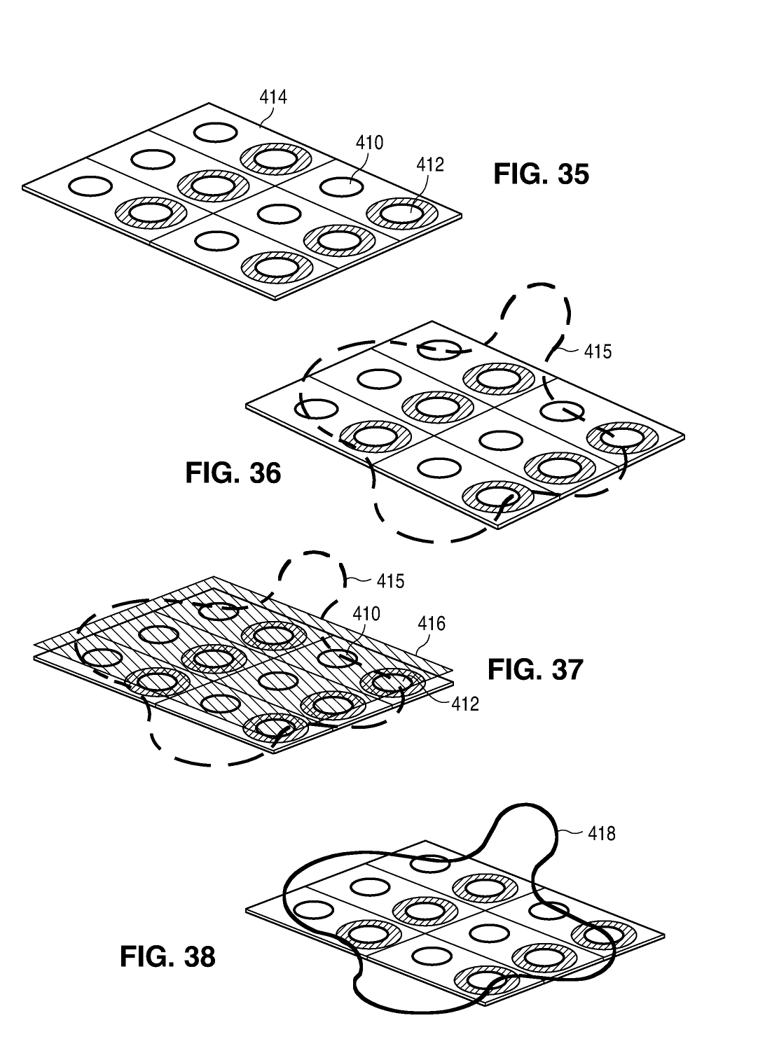

FIGS. 35-40 illustrate a different type of electrode configuration. Instead of conductor strips, metal dots are used for the anode and cathode electrodes 410 and 412 on the bottom surface of each tile. Six tiles 414 are shown, but the sheet of physically connected tiles can be any size. The tiles 414 are initially electrically isolated from each other. The LED areas may take up the entire top surface of each tile 414.

In FIG. 36, the sheet of tiles 414 may be laser-cut to have any shape. An arbitrary shape is shown by the outline 415.

In FIG. 37, a dielectric layer 416 encapsulates the cut edges of the tiles. Openings (not shown) are formed in the dielectric layer 416 to expose the electrodes 410/412 for connection to the backplane.

Multiple segments of a large panel or display may be pieced together.

In FIG. 38, an opaque material 418 may be deposited in any grooves around a segment or around each tile for optical isolation.

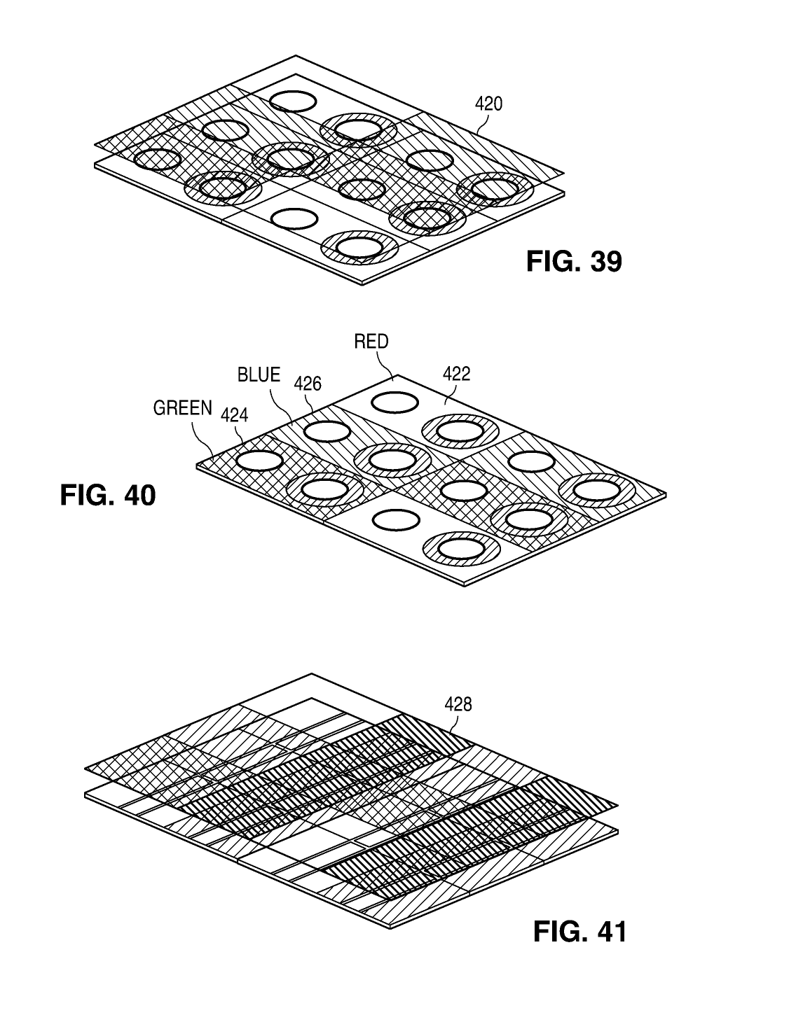

In FIG. 39, assuming the LED areas in the tiles emit white light containing red, green, and blue components, a color filter 420 is laminated over the front side of the tiles to produce RGB pixels. The electrodes on the back side are shown, but may be obscured by the LED areas

FIG. 40 illustrates that the RGB pixels may alternatively be formed by a layer of a red phosphor 422 and a green phosphor 424 over LED areas that emit blue light. The LED area 426 has no phosphor over it so emits blue light.

FIG. 41 illustrates the use of an opaque material 428 around groups of the RGB pixels to improve optical isolation between the pixels. The RGB light emitted from a single pixel area is allowed to mix.

The backplane may include resistors in series with the LED areas to limit current. Other regulation and control circuitry can be used. Linear and switching regulators and LED drivers can be used to more precisely control the voltage and current to the LED tiles. One example uses linear regulator shift registers as an addressable controller. In one embodiment, the design uses 16 overlapping LED tiles that can be cut every 40 mm. The controllers include local PWM dimming which is useful for rending grayscale.

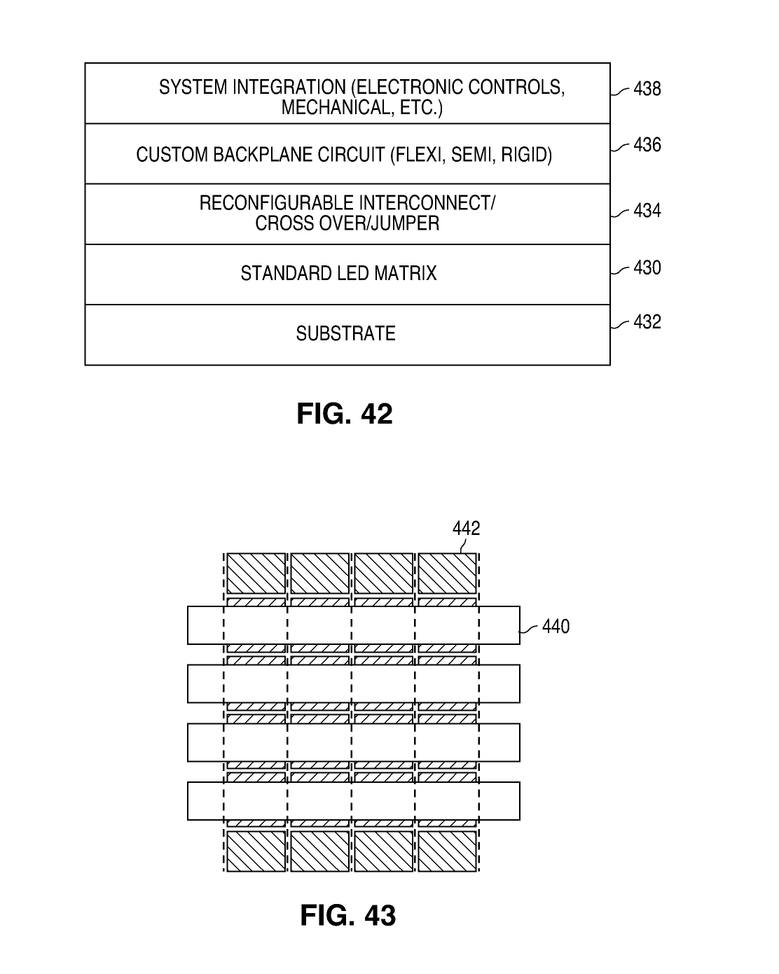

FIG. 42 illustrates another embodiment of layers in a customizable lamp. The printed LED dies and conductor layers (which sandwich the LED dies) form a standard LED matrix 430 over a transparent substrate 432. A configurable middle interconnect layer 434 may be a layered structure that provides cross-over traces and through-hole vias for complex interconnections. The layer 434 may be reconfigurable by programming fuses, switches, etc. Traces on a backplane 436 are configured to further interconnect the various anode and cathode electrodes, such as to form row and/or address lines. Also provided on the backplane 436, or separate from the backplane, is formed active circuitry as a system integration layer 438. This circuitry may be addressing circuitry, processing circuitry, memories, regulators, drivers, etc. for a full color display. The structure may instead be a controllable panel for general illumination or backlighting.

FIG. 43 illustrates a matrix for addressing LED areas in the lamp of FIG. 42. Conductive row 440 lines in the backplane or other interconnection layer may contact anode conductor layers of all the LED tiles in a row. Conductive column lines 442 may contact cathode conductor layers of the all the LED tiles in a column. The printed LED die layer for each tile is generally located between the overlapping column and row lines, and one of the lines is formed of a transparent conductor to allow the LED light to pass through. An LED area at an intersection of an energized row and column is addressed and illuminated. By scanning the LED areas at a frame rate and controlling the current or duty cycle for an addressed LED area, a full color display of any size is provided.

Alternatively, isolated traces connected to each of the LED tile's anode and cathode electrodes are energized for addressing an LED tile, allowing multiple tiles to be addressed simultaneously. Many other types of addressing schemes may be used.

In one embodiment for a color display, red, green, and blue sub-pixels form a single color pixel in the display. For addressing a pixel, all three sub-pixels have their cathodes applied to a common first reference voltage, and the anodes are separately and simultaneously coupled to a suitable current or duty cycle for controlling the relative amounts of red, green, and blue in the pixel.

If the LED tile array is being used for general illumination, the RGB components of the light may be adjusted by separately addressing the red group, green group, and blue group LED tiles.

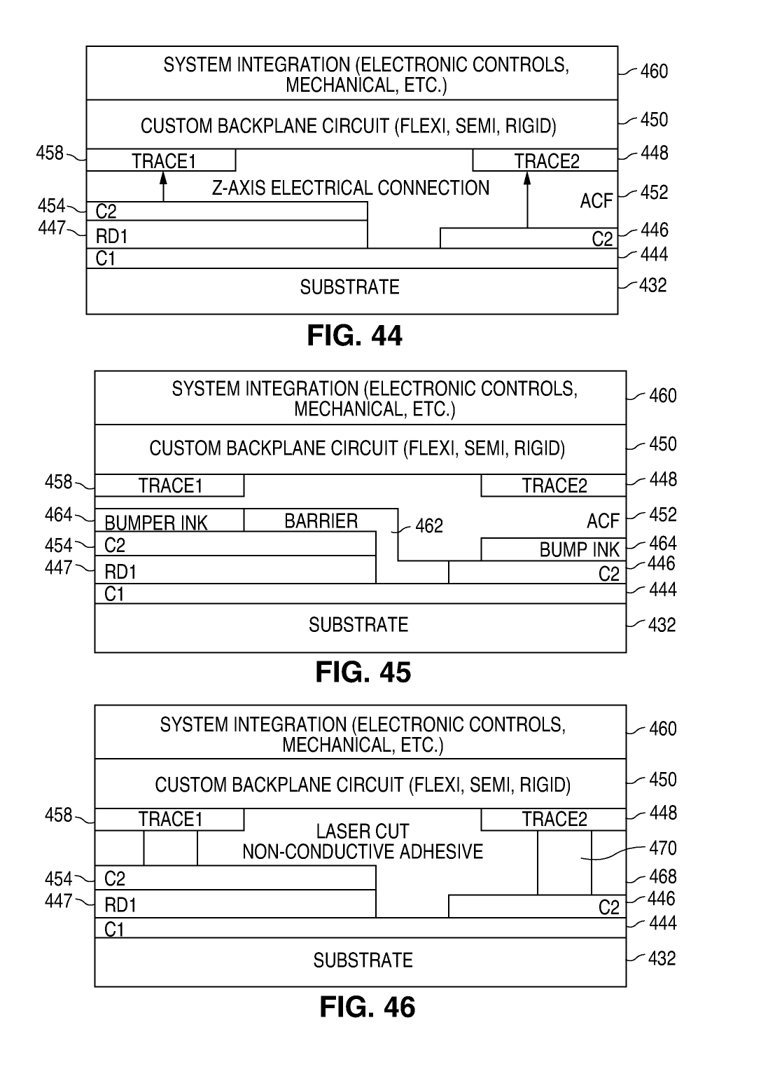

FIG. 44 is a schematic cross-section of a small portion of the addressable LED structure of FIG. 43, showing only one LED tile coupled to a backplane. A row line 444 conductor layer in the tile extends across the substrate 432 and is contacted by an electrode 446. The row line 444 forms the bottom conductor layer for the printed LED die layer 447. The electrode 446 is electrically connected to the trace 448 on the backplane 450 via the compressible ACF layer 452 in the tile. The ACF layer 452 only conducts in the Z direction. A column line 454 conductor layer in the tile forms the top conductor layer for the LED die layer 447, and the column line 454 is electrically connected to the trace 458 by the ACF layer 452. The cured LED die layer 447 is shown at each intersection of the row line 444 and column line 454. The traces 448 and 458 on the backplane form the row and column lines in FIG. 43 external to the LED tiles. The row and column traces are insulated from one another when they cross over. System integration circuitry is provided in the systems integration layer 460. The LED dies are turned on at an energized row and column line intersection using addressing circuitry. As seen, each LED tile comprises the elements 432, 444, 446, 447, 454, and 452 in FIG. 44.

In cases where additional barrier or solder mask layers are used, additional pad thickness might be required to compensate for height differences between the conductive layers. FIG. 45 illustrates the situation where there is a printed dielectric barrier layer 462 for improved isolation. In this case, a conductive bump ink layer 464 is used to increase the conductive planes of the conductors 446 and 454 to equal or exceed the height of the barrier layer 462.

Alternatively, as shown in FIG. 46, a low cost interconnect with high reliability can be created with a unique combination of a robust non-conductive adhesive 468 that is laser cut to create via openings. The vias are filled with highly conductive material 470 such as silver epoxy. This creates very strong adhesive bonds and very low resistance contacts. The preferred adhesive is thermosetting such as 3M™ 583. This adhesive forms strong bonds at low temperatures 100-150° C., which is compatible with temperature-limited materials in the printed lamp. The 3M™ 583 is a common structural adhesive using a phenolic resin and nitrile rubber. The nitrile provides flexibility, and the phenolic provides strength. This material can be laser cut as a dry film to create the via openings. Then the vias can be filled with simple stencil printing of the conductive epoxy. The structure is heated and compressed to harden the adhesive and cure the conductive epoxy.

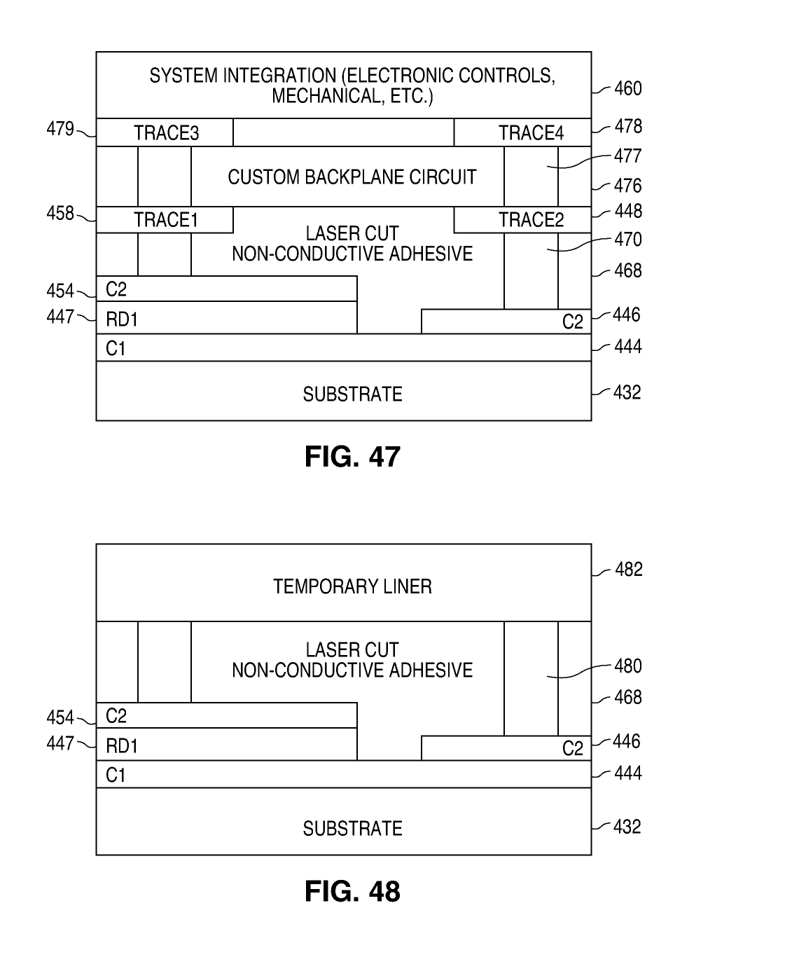

As shown in FIG. 47, the backplane 476 can have two conductive sides to add traces 478 and 479. The traces on opposite sides of the backplane 476 are connected using a through via 477 in the backplane 476. This enables attachment of system components to the backside of the backplane 476. These components can be circuitry for regulating voltage and current of the light, driving multiple lights, controlling addressable light tiles, etc. Components can include resistors, capacitors, inductors, integrated circuits, etc. Electro-mechanical components, such as connectors, can also be attached. These components can be attached by soldering, conductive adhesive, or similar materials.

As shown in FIG. 48, in some applications, the LED tile(s) can be a generic structure delivered to the customer as an adhesive label of any size with any number or tiles. The epoxy-filled conductive vias 480 extend through a non-conductive adhesive 468. A releasable liner film 482 is provided over the vias 480 and adhesive 468. The customer then removes the liner film 482 and attaches the tile to its own circuit board or backplane for customization of the lamp.

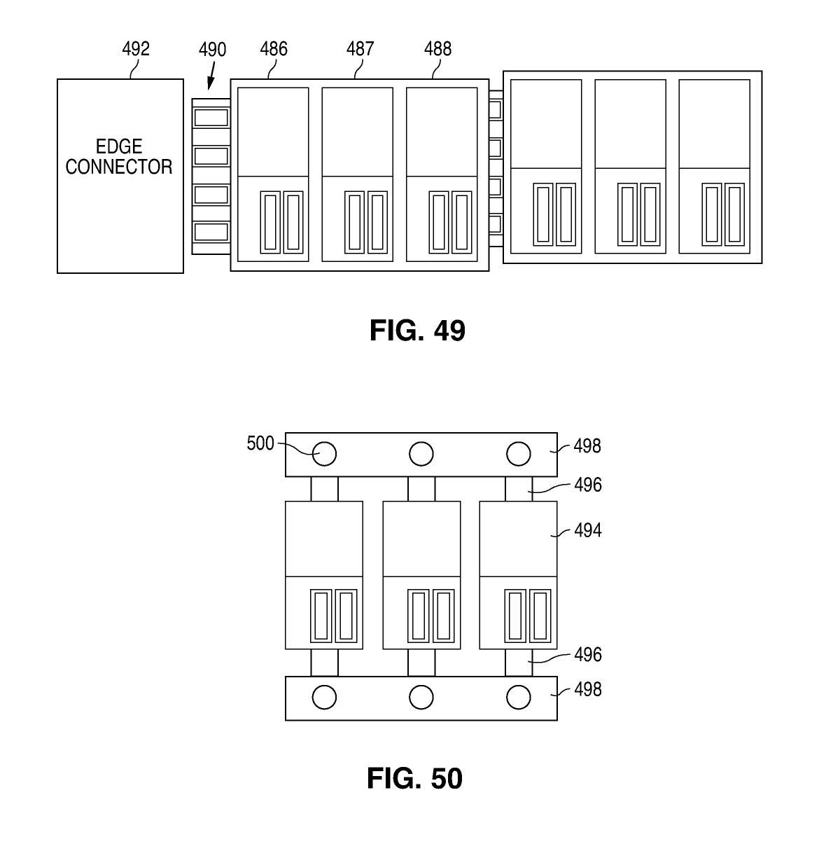

FIG. 49 shows three LED tiles 486-488 forming a single module, where the module has four electrical terminals 490, for coupling to an edge connector 492, with one terminal for each anode and a terminal for a common cathode. Larger modules with more edge connector terminals may also be formed. Identical additional modules may have their edge terminals coupled to a receptacle of another module, so that there is a parallel connection between corresponding LED tiles in each module. The corresponding tiles may all emit the same color, such as red, green, or blue so that the overall color emitted by the interconnected modules may be adjustable. Thus, a customizable string of modules is achieved. Multiple strings of modules may form rows in a large panel. A separate overlapping splice connector could be used as well.

As shown in FIG. 50, mechanical features can be created on a roll of LED tiles 494. In FIG. 50, small breakaway tabs 496 connect adjacent LED tiles 494. Tabs 496 also can connect LED tiles 494 to mechanical rails 498. Rails 498 can be used when aligning the roll of LED tiles 494 to the backplane. Stepper index holes 500 can be punched in the rails 498 for precise alignment to the backplane. Similar features can be created in the backplane. Perforations, V-groove scoring, or similar features can be used instead of breakaway tabs.

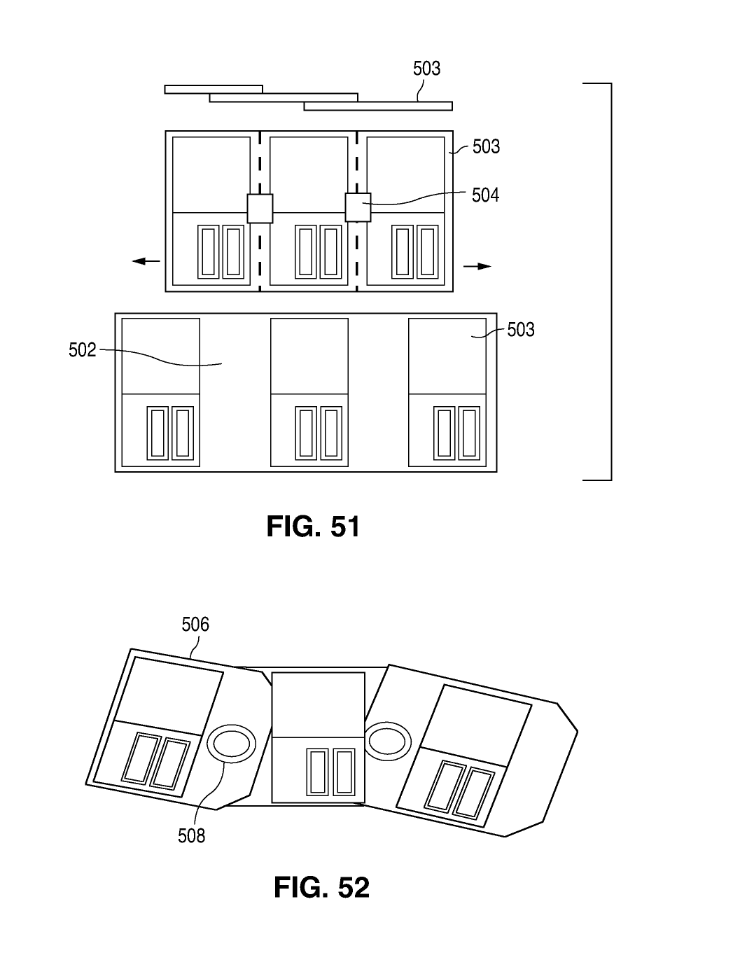

Another application of breakaway features is shown in FIG. 51. FIG. 51 shows a side view of a folded lamp, a front view of the folded lamp, and a front view of the expanded lamp. A backplane 502 can be periodically folded over, doubling its thickness, and compressing its length. Then the lamp roll with breakaway features is bonded to the backplane 502 as previously described. After bonding, the assembly can be pulled lengthwise, breaking the tabs 504 mechanically connecting the tiles 503 together, and expanding the space between lamp titles 503.

In FIG. 52, pivoting joints 508 between LED tiles 506 or modules can be created. The joints 508 can rotate such that the row of LED tiles 506 can be positioned in a non-linear shape. This is particularly useful for backlighting curved graphics such as large letters. To enable a rotating electrical connection, coaxial or concentric contact pads can be created at each pivot point. Alternatively, coplanar pivoting contact pads can be used, or the contact pads can contact different depths or sides of the backplane.

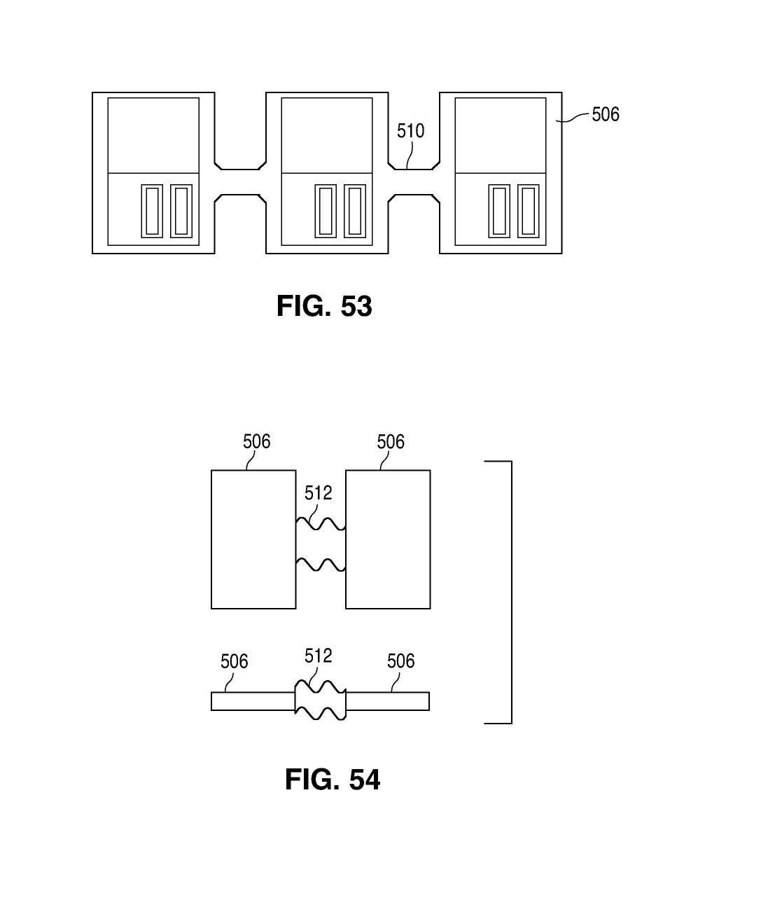

In FIG. 53, the backplane 510 is necked at the joint between LED tiles 506 so that the joint is more flexible. Perforations in the backplane at the joint may be used instead to add flexibility.

In a related embodiment, shown in FIG. 54, the linkage 512 between LED tiles 506 can be a non-linear feature that bends and flexes more easily in the X, Y, and Z directions. FIG. 54 shows a front view and a side view of the structure. A serpentine feature is shown that creates a spring linkage between tiles 506. The non-linear spring feature may be a two dimensional pattern, or the spring feature can be out-of-plane with the backplane as a three dimensional structure.

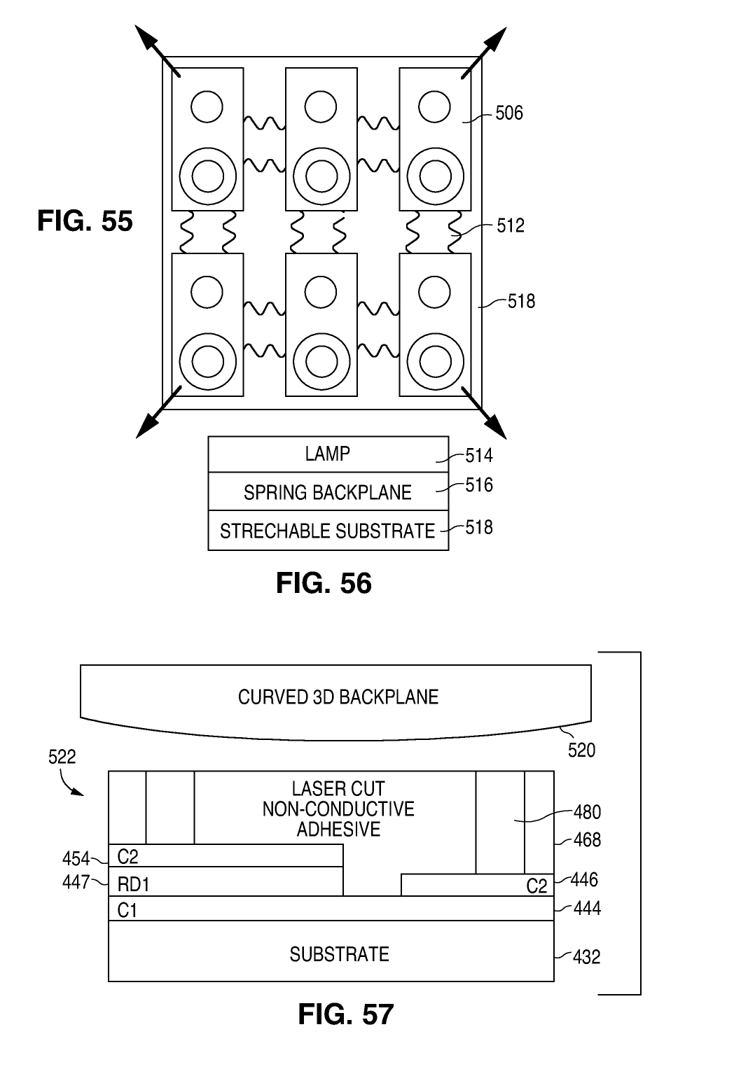

One application of spring linkages is a stretchable lamp sheet, as shown in FIG. 55. In FIG. 55, LED tiles 506 bonded to a backplane with spring linkages 512 can be bonded to a stretchable substrate 518 such as rubber. This stretchable lamp can conform to irregular 3-D surfaces. With this technology, the lamp sheet can be used in many unconventional 3-D applications.

FIG. 56 illustrates the various layers of the structure of FIG. 55, including the lamp layer 514, the backplane with the spring linkages 516, and the stretchable substrate 518.

FIG. 57 is a cross sectional view of a convex backplane 520. The LED tile 522 may be similar to that shown in FIG. 48, with a back surface formed of a compressible adhesive 468 that may be similar to a 3M™ 583 adhesive, with conductive vias 480, such that it can conform to a curved backplane surface when pressure is applied. Then, the adhesive 468 can be thermoset to harden and hold the 3D shape.

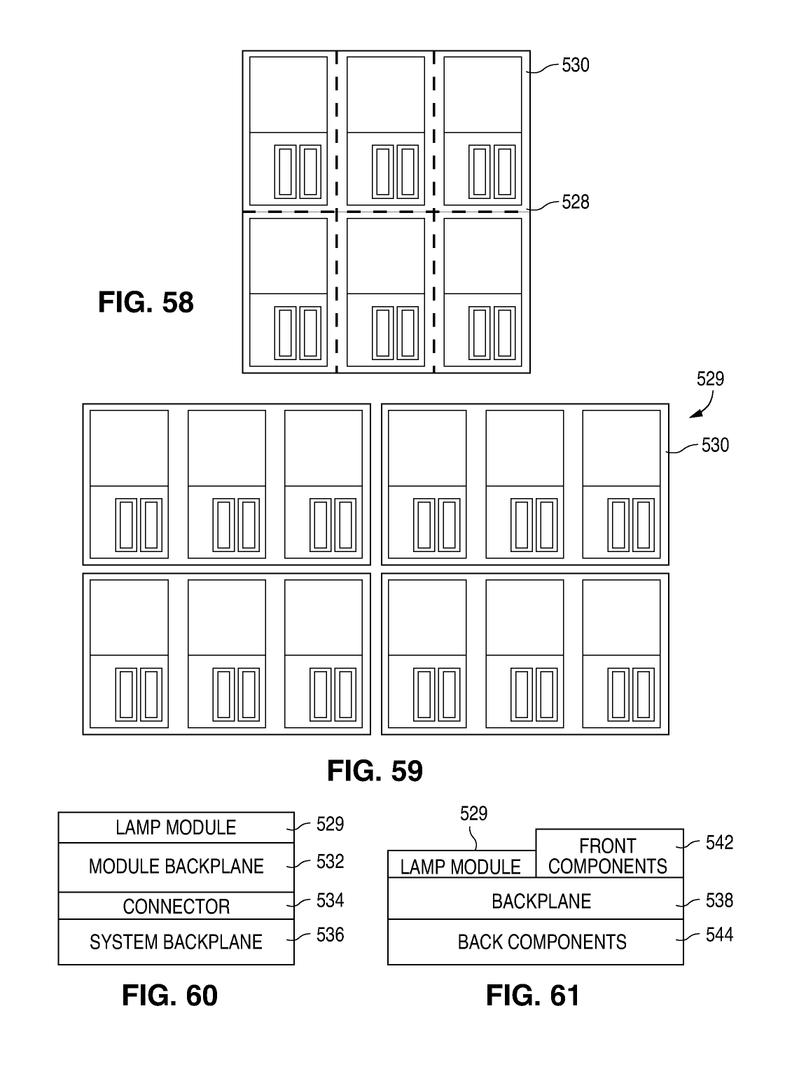

FIG. 58 illustrates flexible areas 528 in the backplane between the LED tiles 530 for bending the structure over curved shapes. The flexible areas 528 can be achieved by tabs, perforations, V-groove scoring, or other structures. These features can also be used to create non-linear or curved shapes. The backplane bends easily at the tab, perforation, or V-groove, similar to a hinge. Metal traces can still conduct across these hinges. Preferably, the traces are on the inside radius so that they are compressed.

As shown in FIG. 59, at the system level, multiple modules 529 of LED tiles 530 (such as addressable RGB tiles) can be interconnected and grouped into a larger assembly. FIG. 59 illustrates four identical modules 529 assembled in an array, which may be four full-color pixels in a large display. Each module 529 may be about 5×10 mm. Large billboard displays can be created using sections of groups of LED tiles that are interconnected during installation and controlled by a single controller or by multiple controllers. Because the system is modular, it is possible to service and replace just defective modules, or groups of modules, rather than replacing the entire system. This architecture can also be used to create large backlights.

FIG. 60 shows the various layers of the large system represented by FIG. 59, including the array of lamp modules 529, backplanes 532 (having interconnecting traces for various groupings of modules), a connector layer 534 for providing additional interconnections between backplanes, and a larger system backplane 536 for providing additional connections, such as to addressing and image processing circuitry.

Electro-mechanical connection from the module backplanes 532 to the system backplane 536 can be pin headers, spring, knuckle contacts or similar conventional board-to-board connectors. In-plane compressive contacts and conductive adhesives can also be used. Clamps, fasteners, and other mechanical hardware can also be used for attachment to other system components and surfaces. Other attachment materials can include magnets, Velcro, and snap fasteners. Stitching with thread could also be used. Also thermal staking, thermal plastic bonding, and ultrasonic bonding are other methods of attachment.

Components can be mounted on both sides of the backplane.

FIG. 61 illustrates component attachment on both sides of the backplane 538. Front components 542 are coplanar with the lamp modules 529. Such front components 542 could be a capacitive touch sensor or a photo diode. Back components 544 could be, for example, sensor amplifiers and control logic. Conductive through-vias in the backplane connect the front components 542 to the back components 544.

Backplane materials can be printed ink on plastic substrates such as PET. Other flexible substrates like copper clad polyimide are also possible. Foils and PVD metals can also be clad on PET and other low temperature substrates flexible substrates. Conventional rigid circuit boards such as copper clad FR4 are also possible. 3D backplanes can be created by embedding or otherwise attaching conductors in injection molded plastic forms.

The invention of mounting identical tiles on a configurable backplane can also be applied to photovoltaic (PV) tiles.

In a conventional PV panel, sunlight impinges on doped semiconductor material forming a pn junction, such as Si or Ga, to generate current at a certain voltage. A conventional PV panel typically comprises a flexible thin sheet (less than 1 mm) containing an array (e.g., 10×6) of thin silicon areas (cells) forming pn junctions, where an upper and lower metal pattern electrically contact the anode and cathode of each cell to permanently connect the cells in any combination of series and parallel to achieve a desired voltage and current from the panel. The metal interconnects and semiconductor layers are integrally formed on the same thin substrate. In one conventional panel, although each cell only generates about 0.5 volts, the cells are interconnected so that the panel outputs about 12 volts, with a maximum current of about 4 Amps. Any other voltage and current can be obtained by interconnecting the cells. The thin sheet is mounted on an electrically isolated framed support for rigidity. An anode and cathode electrode of the panel is typically provided by two wires or an electrical connector so multiple panels can be further interconnected by the user to achieve a desired voltage and current. Thus, the mass-produced flexible PV sheet, containing the various metal interconnections between cells, is not configurable for a particular application. Only the connections between PV panels are configurable by connecting the panels together with external wires.

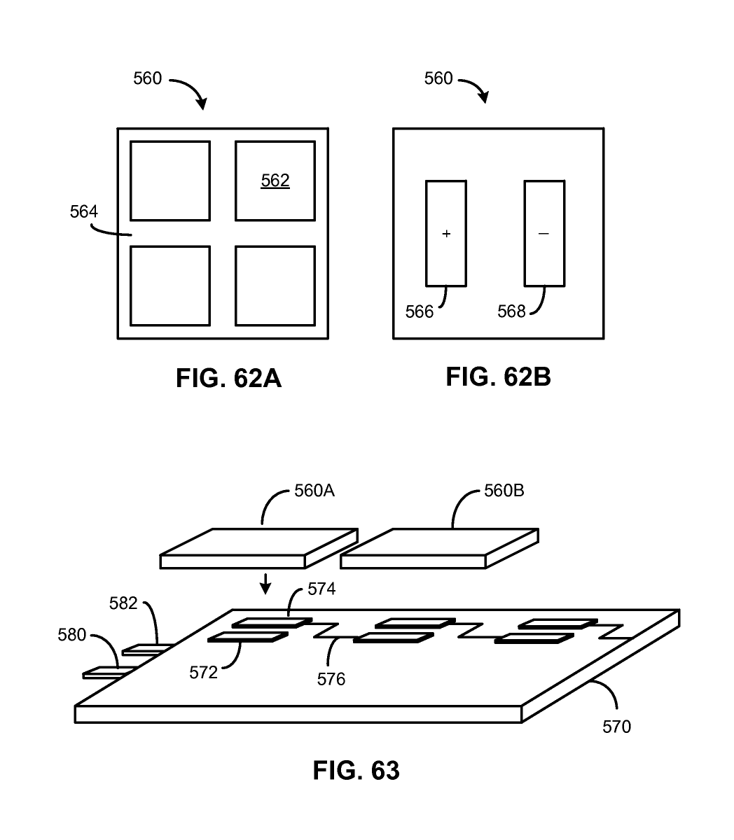

FIGS. 62-63 illustrate the use of an inexpensively configurable backplane that electrically interconnects identical PV tiles together in any manner while also providing the required mechanical support for the thin PV tiles.

FIG. 62A is a front view of a PV tile 560 having four PV cells 562. The tile 560 can have any number of cells 562. Each cell 562 is basically a layer of a doped semiconductor forming a pn junction, which typically outputs about 0.5 volts when energized by sunlight. A metal pattern on the tile 560 is represented by metal traces 564 between the cells 562 to connect the tops (e.g., anodes) of the semiconductor layers in parallel. In another embodiment, the metal traces 564 can connect the cells 562 in any combination of series and parallel to achieve a desired current and voltage from the tile 560. Another metal pattern (not shown) internal to the tile 560 may similarly connect all the bottoms (e.g., cathodes) of the semiconductor layers together for the parallel connection. In another embodiment, the metal traces connect the cells 562 in any combination of series and/or parallel.

FIG. 62B illustrates the back surface of the tile 560, where the upper and lower metal traces terminate in a large metal anode electrode 566 and a large metal cathode electrode 568.

Each tile 560 may be, for example, 4×4 inches, 12×12 inches, or any other size and may contain any number of cells 562.

Each tile 560 may be formed using printing under atmospheric conditions, where a reflective conductor layer (e.g., aluminum) is provided on a thin, flexible substrate, where a monolayer (for each cell 562) of silicon micro-spheres is then printed over the conductor layer and doped to form a pn junction in each micro-sphere, where a dielectric layer is then formed over the conductor layer while exposing the tops of the micro-spheres, and where a transparent conductor is then printed over the tops of the spheres (e.g., the n-type side) to connect the micro-spheres diodes in parallel. Sunlight enters through the transparent conductor layer. Printed metal traces, formed on the surface and/or formed as a separate layer in the tile, then connect to the conductor layers to connect the cells 562 in parallel, or in any combination of series and/or parallel. Conductive vias through the substrate, or metal straps, are then used to electrically connect the conductor layers to the respective anode electrode 566 and cathode electrode 568 on the back surface of the tiles 560. The tiles 560 may be formed as an initially large sheet in a roll-to-roll process. The tiles 560 are then singulated from the sheet. Each tile will typically be a fraction of a millimeter thick. In one embodiment, all tiles 560 will output about 0.5 volts and may generate up to 4 Amps in direct sunlight.

FIG. 63 illustrates two identical tiles 560A and 560B being mounted on a configurable backplane 570. It is inexpensive to provide a customized metal pattern on the backplane 570 since no testing needs to be done. The backplane 570 substrate is a dielectric, such as a plastic. The backplane 570 includes metal electrodes 572 and 574 for each tile 560 that are aligned with the electrodes 566/568 on the back of each tile 560. A customizable metal pattern 576 interconnects the backplane electrodes 572/574 in any configuration to connect the tiles 560 in any combination of series and parallel so that the output of the backplane can be any variation of voltage and current. The backplane 570 may have any form of output connector, such as two wires (anode and cathode), a male socket, a female socket, etc. to further interconnect multiple backplanes 570 together or to connect the backplane 570 to a suitable power converter. The output of the backplane 570 is shown as a male anode terminal 580 (electrode) and a male cathode terminal 582 (electrode) for receiving female connectors, such as for interconnecting multiple backplanes. The backplane 570 also provides the required mechanical support for the flexible tiles 560 for installation. A conductive epoxy may be used to permanently affix the tile electrodes to the backplane electrodes.

In one embodiment, each backplane 570 is about the size of a conventional PV panel.

In another embodiment, the backplanes 570 are relatively small and a much larger super-backplane, having another configurable metal pattern, may be used to interconnect multiple backplanes 570 together. In such an embodiment, the backplanes 570 are provided with rear anode and cathode electrodes (formed as metal pads), or the connection to the super-backplane is done in another manner. The super-backplane has top electrodes that align with the electrodes on the back surface of the backplane 570. Connections between electrodes may be accomplished using a conductive epoxy or by other means. In such a case the backplanes 570 may be very thin, and the rigidity is provided by the super-backplane. In one embodiment, the super-backplane is about the size of a conventional PV panel.

Accordingly, complex, customized interconnections between the various PV cells can be achieved without changing the design of the tiles 560. Fuses, or other programmable interconnections on the backplane 570, may also be used to customize the various metal interconnections by the user.

In other embodiments, other circuits may be included in the tiles, such as batteries, sensors, transistors, logic circuits, etc.

Customizable light systems and PV systems have been described. Unique end products can be created using standardized printed LED tiles or PV tiles in combination with configurable interconnects and custom backplanes. The cost of the end products will be reduced since the tiles may be standardized, and the easily customizable backplane has a very high reliability due to its simplicity. In addition to the configurable end products previously described herein (e.g., displays, general lighting, backlighting, etc.), some other end products are described below.

Illuminated signs may be freely configured by the user or manufacturer, such as store signs or road signs, by forming the LED tiles as different letters or words and temporarily or permanently mounting the tiles on a backplane having the electrical connectors. A weak releasable adhesive or other securing method may be used to temporarily attach the tiles to the backplane to create a changeable sign. Direction arrows and other designs may also be formed. Any ornamental design can also be created. This also applies to the related fields of advertising, billboards, street signs, etc. The backplane and tiles may also be configured as an addressable display, such as for a scrolling sign.

Toys and other amusement devices may entail mounting LED tiles on a backplane, such as for forming designs or for achieving a goal of a game.

The LED tiles may be adapted for use in or on a vehicle. For example, a backplane may be provided as the ceiling in an automobile, or for signaling lights, to provide power, and the manufacturer then mounts LED tiles to the backplane to achieve the desired purpose of lighting or signaling. By using multiple tiles in a system, the failure of any one tile will not require the entire lighting system to be replaced, since only that tile can be replaced or eliminated during testing. The signaling tiles may emit red, yellow, amber, etc. and the interior lighting tiles may emit white light. A customized arrangement of LED tiles may be mounted on a backplane for backlighting an emblem, such as an automobile logo, or other customized shape. Vehicle side mirrors frequently include a signal light for turning, and the minor may be configured with a backplane with one or more LED tiles mounted on it for signaling.

The tiles and backplane may also be configured for accent lights, decorative lights, signaling lights, or safety lights on clothing, furniture, belts, cups, shoes, smartphones, smartphone covers, etc.

The tiles and backplane may be used to create a customized lighting design for vanity lights, under-cabinet lights, narrow light panels, refrigerators, etc.

The backplane and tiles may be provided as very thin and flexible rolls or strips for ease of handling and transportation.

Other customizable applications of the LED tiles and backplane include:
Backlighting keyboards, keypads, graphics, signs, etc.;
Attraction-getting displays for packaging;
Integrating the tiles/backplane into consumer devices for controls, logos, etc.;
Self-powered disposable lighting units and safety strips with integrated photovoltaic devices and batteries;
Reading lights and other directed lights;
Illuminating the ends of medical devices such as dental devices and endoscopes;
Lining interior walls with flat light sheets;
Illumination under or above shelves;
Modular light sheet sections that interconnect together;
Using UV LEDs in the LED tiles for sanitization;
Creating controllable colors;
Forming light strips as an adhesive tape;
Unrolling light sheets to create portable signs, safety cones, etc.;
Lighting walkways and providing guide paths;
Reflective displays that use either the sun or an LED sheet as the light source;
Color or monochrome addressable displays having printed LEDs in pixel areas;
Light or image sensors having printed photodiodes;
Visual entertainment systems;
Bending or molding the light sheet to achieve desired light emission characteristics;
Building accents;
Illuminating various sporting devices;
Dynamically addressable backlighting of graphics to achieve animation;
Forming 3-D displays by stacking transparent tiles and backplanes.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. An illumination structure comprising:
a plurality of tiles, each tile comprising:
a first conductive layer;
a plurality of inorganic light emitting diode dies (LEDs) printed as an LED layer, the LEDs having a first electrode electrically contacting the first conductive layer;
a transparent second conductive layer overlying the LEDs and electrically contacting a second electrode of the LEDs to connect the LEDs in parallel;
a first terminal in electrical contact with the first conductive layer; and
a second terminal in electrical contact with the second conductive layer;
a conductive backplane fabricated separately from the tiles, the backplane comprising:
a dielectric backplane substrate; and
a metal pattern formed on the backplane substrate,
wherein the plurality of the tiles is mounted over the metal pattern such that the first terminal and the second terminal of each of the tiles are electrically connected to the metal pattern, wherein the metal pattern supplies power to the tiles for energizing the LEDs.

2. The structure of claim 1 wherein the tiles are formed on a common flexible substrate so as to be mechanically connected together.

3. The structure of claim 1 wherein the tiles are physically separated from one another.

4. The structure of claim 1 wherein the metal pattern connects at least some of the tiles in series.

5. The structure of claim 1 wherein the metal pattern connects at least some of the tiles in parallel.

6. The structure of claim 1 wherein the metal pattern comprises row strips and column strips such that a single tile can be selectively energized by applying a voltage between a row strip and a column strip.

7. The structure of claim 1 wherein the segments mounted over the metal pattern form a lamp for general lighting.

8. The structure of claim 1 wherein the tiles mounted over the metal pattern form an addressable display.

9. The structure of claim 1 wherein the tiles and backplane are flexible, and the tiles are laminated over the backplane.

10. The structure of claim 1 further comprising a conductive adhesive layer over the backplane substrate that is affixed to a bottom surface of the tiles.

11. The structure of claim 1 wherein the metal pattern comprises at least two levels of metal layers.

12. The structure of claim 1 wherein the LEDs are microscopic vertical LEDs.

13. The structure of claim 1 wherein all the tiles emit the same color of light.

14. The structure of claim 1 wherein the tiles emit a variety of colors of light.

15. The structure of claim 1 wherein the backplane is flexible between the tiles.

16. The structure of claim 1 wherein the tiles are equal to or less than 10 x10 mm and form addressable pixels in a display.

17. The structure of claim 1 wherein LED tiles are mechanically coupled together prior to being mounted on the backplane, wherein the backplane electrically interconnects the LED tiles.

18. The structure of claim 1 wherein the metal pattern on the backplane individually addresses any of the tiles.

19. The structure of claim 1 wherein each of the tiles has a compressible adhesive layer for affixing to the backplane.

20. The structure of claim 1 wherein the backplane is stretchable between the tiles.

21. A photovoltaic structure comprising:
a plurality of tiles, each tile comprising:
one or more photovoltaic cells configured for receiving sunlight through a top surface, each cell having an anode and a cathode; and
a first metal pattern connecting the anodes and cathodes of the one or more photovoltaic cells to a first anode electrode and a first cathode electrode formed on a bottom surface of each of the tiles;
a conductive backplane fabricated separately from the tiles, the backplane comprising:
a dielectric backplane substrate; and
a second metal pattern formed on the backplane substrate,
wherein the plurality of the tiles is mounted over the second metal pattern such that the first anode electrode and the second cathode electrode of each of the tiles are electrically connected to the second metal pattern, wherein the second metal pattern interconnects the first anode electrodes and first cathode electrodes of the tiles; and
an output of the backplane comprising a second anode electrode and a second cathode electrode.

22. The structure of claim 21 wherein the first metal pattern connects the photovoltaic cells at least in series.

23. The structure of claim 21 wherein the first metal pattern connects the photovoltaic cells at least in series.

24. The structure of claim 21 wherein the second metal pattern connects the first anode electrodes and first cathode electrodes of the tiles at least in series.

25. The structure of claim 21 wherein the second metal pattern connects the first anode electrodes and first cathode electrodes of the tiles at least in parallel.

26. The structure of claim 21 wherein the second anode electrode and the second cathode electrode of the backplane are formed as electrical connectors.

27. The structure of claim 21 wherein the second anode electrode and the second cathode electrode of the backplane are formed as metal pads on a bottom surface of the backplane.
